(19) United States
(12) Patent Application Publication
(10) Pub. No.: US 2024/0397754 A1
(43) Pub. Date: Nov. 28, 2024

(54) DISPLAY PANEL AND METHOD OF FABRICATING THE SAME

(71) Applicant: Samsung Display Co., LTD., Yongin-si (KR)

(72) Inventors: HYUNEOK SHIN, Yongin-si (KR); JOONYONG PARK, Yongin-si (KR); SUKYOUNG YANG, Yongin-si (KR); DONGMIN LEE, Yongin-si (KR)

(21) Appl. No.: 18/630,662

(22) Filed: Apr. 9, 2024

(30) Foreign Application Priority Data
May 26, 2023 (KR) 10-2023-0068669

(51) Int. Cl. H10K 59/122; G09G 3/32; H10K 59/12; H10K 59/80

(52) U.S. Cl. CPC H10K 59/122; G09G 3/32; H10K 59/1201; H10K 59/80521; G09G 2300/0819; G09G 2300/0852

(57) ABSTRACT

A display panel includes a base layer, a pixel definition layer on the base layer, where an emission opening is defined in the pixel definition layer, a partition wall including a first partition layer on the pixel definition layer, a second partition layer on the first partition layer, where a partition opening is defined in the partition wall to overlap the emission opening, an emission element including an anode, an intermediate layer on the anode, and a cathode on the intermediate layer, and a subsidiary electrode on the emission element. The intermediate layer and the cathode are spaced apart from a lateral surface of the partition wall when viewed in plan. The subsidiary electrode is in contact with the partition wall.

This application claims priority to Korean Patent Application No. 10-2023-0068669, filed on May 26, 2023, and all the benefits accruing therefrom under 35 U.S.C § 119, the content of which in its entirety is herein incorporated by reference.

### BACKGROUND

### 1. Field

Embodiments of the invention relate to a display panel and a method of fabricating the display panel, and more particularly, to a display panel having improved display quality and a method of fabricating the display panel.

### 2. Description of the Related Art

A display panel, which displays an image, is typically included in a display device, such as a television, a monitor, a smart phone, and a tablet computer, which provides images to users. Various types of display panel, such as liquid crystal display panels, organic light emitting display panels, electro-wetting display panels, and electrophoretic display panels, have been developed.

An organic light emitting display panel may include an anode, a cathode, and an emission pattern. The emission pattern may be divided for each emission region, and the cathode may provide a common voltage to each emission region.

### SUMMARY

Embodiments of the invention provide a display panel having improved display quality and a method of fabricating the display panel in which an emission element is formed without using a metal mask.

According to an embodiment of the invention, a display panel includes: a base layer; a pixel definition layer on the base layer, where an emission opening is defined in the pixel definition layer; a partition wall including a first partition layer on the pixel definition layer and a second partition layer on the first partition layer, where a partition opening is defined in the partition wall to overlap the emission opening; an emission element including an anode, an intermediate layer on the anode, and a cathode on the intermediate layer; and a subsidiary electrode on the emission element. In such an embodiment, the intermediate layer and the cathode are spaced apart from a lateral surface of the partition wall when viewed in plan. In such an embodiment, the subsidiary electrode is in contact with the partition wall.

In an embodiment, the subsidiary electrode may cover both ends of the intermediate layer and both ends of the cathode.

In an embodiment, the subsidiary electrode may be in contact with a first inner lateral surface of the first partition layer and electrically connected to the partition wall.

In an embodiment, the subsidiary electrode may include titanium nitride (TiN).

In an embodiment, the subsidiary electrode may extend along a first inner lateral surface of the first partition layer.

In an embodiment, the subsidiary electrode may extend along a first inner lateral surface of the first partition layer and a bottom surface of the second partition layer.

In an embodiment, the second partition layer may include a tip which protrudes from the first partition layer toward a center of the partition opening. In such an embodiment, a length in a first direction of the tip may be equal to or greater than about 1.5 times a thickness of the first partition layer.

In an embodiment, a thickness of the second partition layer may be in a range of about 2,000 angstrom (Å) to about 3,000 Å.

According to an embodiment of the invention, a display panel includes: a base layer; a pixel definition layer on the base layer, where an emission opening is defined in the pixel definition layer; a partition wall including a first partition layer on the pixel definition layer and a second partition layer on the first partition layer, where a partition opening is defined in the partition wall to correspond to the emission opening; an emission element including an anode, an intermediate layer on the anode, and a cathode on the intermediate layer; and a subsidiary electrode on the emission element. In such an embodiment, the second partition layer includes a tip which protrudes from the first partition layer toward a center of the partition opening. In such an embodiment, a length in a first direction of the tip may be equal to or greater than about 1.5 times a thickness of the first partition layer.

In an embodiment, the intermediate layer and the cathode may be spaced apart from a lateral surface of the partition wall when viewed in plan. In such an embodiment, the subsidiary electrode may be in contact with the partition wall.

In an embodiment, the subsidiary electrode may cover both ends of the intermediate layer and both ends of the cathode.

In an embodiment, the subsidiary electrode may be in contact with a first inner lateral surface of the first partition layer and electrically connected to the partition wall.

In an embodiment, the subsidiary electrode may include titanium nitride (TiN).

In an embodiment, the subsidiary electrode may extend along a first inner lateral surface of the first partition layer.

In an embodiment, the subsidiary electrode may extend along a first inner lateral surface of the first partition layer and a bottom surface of the second partition layer.

In an embodiment, a thickness of the second partition layer may be in a range of about 2,000 Å to about 3,000 Å.

According to an embodiment of the invention, a method of fabricating a display panel includes: providing a preliminary display panel which includes a base layer, a pixel definition layer on the base layer, a first preliminary partition layer on the pixel definition layer, and a second preliminary partition layer on the first preliminary partition layer; etching the first preliminary partition layer and the second preliminary partition layer to form a first partition layer and a second partition layer with partition openings defined therein; forming in the partition openings an emission pattern and a cathode, which are spaced apart from the second partition layer when viewed in plan; and forming on the cathode a subsidiary electrode in contact with the first partition layer, where the subsidiary electrode includes titanium nitride (TiN).

In an embodiment, the forming the emission pattern and the cathode may include performing a thermal evaporation process.

In an embodiment, the forming the subsidiary electrode may include performing a sputtering process.

In an embodiment, the forming the subsidiary electrode may include depositing a preliminary subsidiary electrode to cover both ends of the emission pattern and both ends of the cathode.

In an embodiment, the forming the first partition layer and the second partition layer may include forming on the second partition layer a tip which protrudes from the first partition layer toward a center of the partition openings. In such an embodiment, a length in a first direction of the tip may be equal to or greater than about 1.5 times a thickness of the first partition layer.

### BRIEF DESCRIPTION OF DRAWINGS

FIG. 1A illustrates a perspective view showing a display device according to an embodiment of the invention.

FIG. 1B illustrates an exploded perspective view showing a display device according to an embodiment of the invention.

FIG. 2 illustrates a cross-sectional view showing a display module according to an embodiment of the invention.

FIG. 3 illustrates a plan view showing a display panel according to an embodiment of the invention.

FIG. 4 illustrates an equivalent circuit diagram showing a pixel according to an embodiment of the invention.

FIG. 5 illustrates an enlarged plan view partially showing a display region of a display panel according to an embodiment of the invention.

FIG. 6 illustrates a cross-sectional view taken along line I-I′ of FIG. 3, showing a display panel according to an embodiment of the invention.

FIG. 7 illustrates an enlarged cross-sectional view of section AA′ of FIG. 6.

FIG. 8 illustrates a cross-sectional view taken along line II-II′ of FIG. 5.

FIG. 9 illustrates a cross-sectional view taken along line I-I′ of FIG. 3, showing a display panel according to an embodiment of the invention.

FIGS. 10A to 10J illustrate cross-sectional views showing some steps in a method of fabricating a display panel according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this description, when a certain component (or region, layer, portion, etc.) is referred to as being “on”, “connected to”, or “coupled to” other component(s), the certain component may be directly on, directly connected to, or directly coupled to the other component(s) or at least one intervening component may be therebetween.

Like numerals indicate like components. Moreover, in the drawings, thicknesses, ratios, and dimensions of components are exaggerated for effectively explaining the technical contents.

It will be understood that, although the terms first, second, etc. may be used herein to describe various components, these components should not be limited by these terms. These terms are only used to distinguish one component from another component. For example, a first component could be termed a second component, and vice versa without departing from the scope of the invention.

In addition, the terms “beneath”, “lower”, “above”, “upper”, and the like are used herein to describe one component's relationship to other component(s) illustrated in the drawings. The relative terms are intended to encompass different orientations in addition to the orientation depicted in the drawings.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms used herein including technical and scientific terms have the same meaning generally understood by one of ordinary skilled in the art. Also, terms as defined in dictionaries generally used should be understood as having meaning identical or meaning contextually defined in the art and should not be understood as ideally or excessively formal meaning unless definitely defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

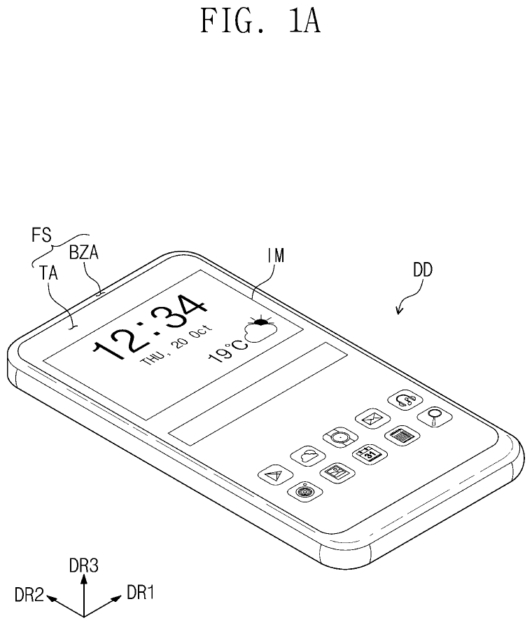

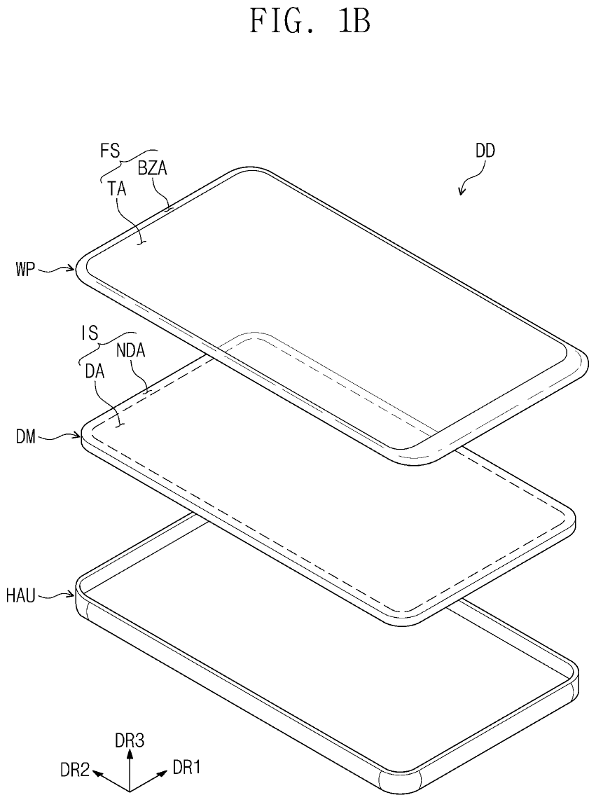

FIG. 1A illustrates a perspective view showing a display device DD according to an embodiment of the invention. FIG. 1B illustrates an exploded perspective view showing a display device DD according to an embodiment of the invention.

The display device DD according to an embodiment may be a large-sized display apparatus for televisions, monitors, or outdoor billboards. In addition, the display device DD may be a small and medium-sized display apparatus for personal computers, laptop computers, personal digital terminals, automotive navigation units, game consoles, smart phones, tablet computers, or cameras. This, however, is merely an example, and other types display apparatus may be adopted as long as not deviated from the teaching herein. FIGS. 1A and 1B illustrate an embodiment where the display device DD is a smart phone as an example.

Referring to FIGS. 1A and 1B, an embodiment of the display device DD may display an image IM in a third direction DR3 on a display surface FS parallel to each of a first direction DR1 and a second direction DR2. The third direction DR3 may be a normal direction to a plane defined by the first direction DR1 and the second direction DR2. The image IM may include not only dynamic images but also static images. FIG. 1A shows a clock window and icons as an example of the image IM. The display surface FS on which the image IM is displayed may correspond to a front surface of the display device DD.

In an embodiment, front and rear surfaces (or top and bottom surfaces) of each component are defined based on a direction along which the image IM is displayed. The front and rear surfaces may be opposite to each other in the third direction DR3, and a normal direction to each of the front and rear surfaces may be parallel to the third direction DR3. Directions indicated by the first, second, and third directions DR1, DR2, and DR3 are relative concepts and may denote other directions. In this description, the phrase “when viewed in plane” or “when viewed in a plan view” may mean “when viewed in the third direction DR3.”

In an embodiment, the display device DD may include a window WP, a display module DM, and a housing HAU. The window WP and the housing HAU may be combined with each other to constitute an appearance of the display device DD.

The window WP may include an optically transparent dielectric material. For example, the window WP may include glass or plastic. A front surface of the window WP may define the display surface FS of the display device DD. The display surface FS may include a transmission region TA and a bezel region BZA. The transmission region TA may be an optically transparent region. In an embodiment, for example, the transmission region TA may be a region whose visible-light transmittance (i.e., light transmittance with respect to visible light) is equal to or greater than about 90%.

The bezel region BZA may be a region whose optical transmittance is relatively less than that of the transmission region TA. The bezel region BZA may define a shape of the transmission region TA. The bezel region BZA may be adjacent to and surround the transmission region TA. This, however, is merely an example, and the bezel region BZA may be omitted from the window WP. The window WP may include at least one function layer selected from an anti-fingerprint layer, a hard coating layer, and an antireflection layer, but the invention is not limited to a particular embodiment.

The display module DM may be disposed below the window WP. The display module DM may be a component that substantially generates the image IM. The image IM generated from the display module DM may be displayed on a display surface IS of the display module DM, and may be outwardly visible through the transmission region TA to users.

The display module DM may include a display region DA and a non-display region NDA. The display region DA may be a region activated with an electrical signal. The non-display region NDA may be adjacent to the display region DA. The non-display region NDA may surround the display region DA. The non-display region NDA may be covered with the bezel region BZA, and may thus not be outwardly visible.

The housing HAU may be combined with the window WP. The housing HAU and the window WP may be combined with each other to provide an inner space. The display module DM may be accommodated in the inner space.

The housing HAU may include a material whose rigidity is relatively high. In an embodiment, for example, the housing HAU may include at least one selected from glass, plastic, and metal, or may include a plurality of frames and/or plates each including at least one selected from glass, plastic, and metal. The housing HAU may stably protect, from external impact, components of the display device DD that are accommodated in the inner space.

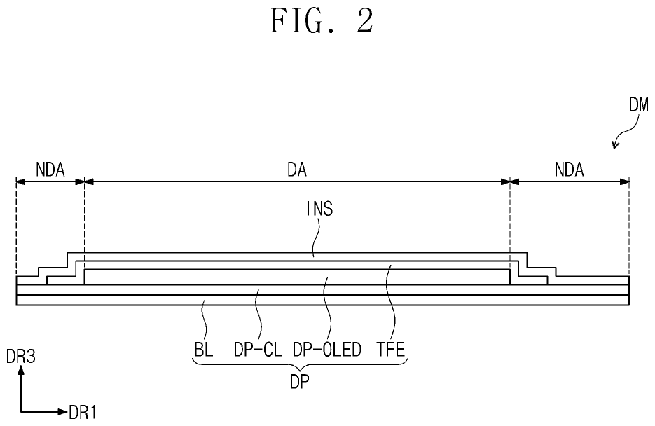

FIG. 2 illustrates a cross-sectional view showing the display module DM according to an embodiment of the invention.

Referring to FIG. 2, an embodiment of the display module DM may include a display panel DP and an input sensor INS. Although not shown, the display device (see DD of FIG. 1A) according to an embodiment of the invention may further include a protection member disposed on a bottom surface of the display panel DP, or an antireflection member or a window member disposed on a top surface of the input sensor INS.

The display panel DP may be an emissive display panel. This, however, is merely an example, and the invention is not particularly limited thereto. in an embodiment, for example, the display panel DP may be an organic light emitting display panel or an inorganic light emitting display panel. An emission layer in the organic light emitting display panel may include an organic light emitting material. An emission layer in the inorganic light emitting display panel may include a quantum-dot, a quantum-rod, or a micro-light emitting diode (LED). Hereinafter, for convenience of description, embodiments in which the display panel DP is an organic light emitting display panel will be described in detail.

The display panel DP may include a base layer BL and may also include a circuit element layer DP-CL, a display element layer DP-OLED, and a thin encapsulation layer TFE that are disposed on the base layer BL. The input sensor INS may be directly disposed on the thin encapsulation layer TFE. In this description, the phrase “A component is directly disposed on B component” may mean that no adhesion layer is disposed between A component and B component.

The base layer BL may include at least one plastic film. The base layer BL may include a flexible substrate, for example, a plastic substrate, a glass substrate, a metal substrate, or an organic/inorganic composite substrate. The display region DA and the non-display region NDA shown in FIG. 1B may be considered as being defined on the base layer BL.

The circuit element layer DP-CL may include at least one dielectric layer and a circuit element. The dielectric layer may include at least one inorganic layer and at least one organic layer. The circuit element may include a signal line, a pixel driver circuit, and the like.

The display element layer DP-OLED may include a partition wall and an emission element. The emission element may include an anode, an intermediate layer, and a cathode.

The thin encapsulation layer TFE may include a plurality thin layers. In such an embodiment, one thin layer may be provided for increase in optical efficiency, and another thin layer may be provided for protection of organic light emitting diodes.

The input sensor INS may obtain coordinate information of external input. The input sensor INS may have a multi-layered structure. The input sensor INS may include a single or multiple conductive layer. In addition, the input sensor INS may include a single or multiple dielectric layer. The input sensor INS may use a capacitance method to detect external inputs. This, however, is merely an example, and the invention is not limited thereto. For example, in an embodiment, the input sensor INS may detect external inputs by using an electromagnetic induction method or a pressure sensing method. In another embodiment of the invention, the input sensor INS may be omitted.

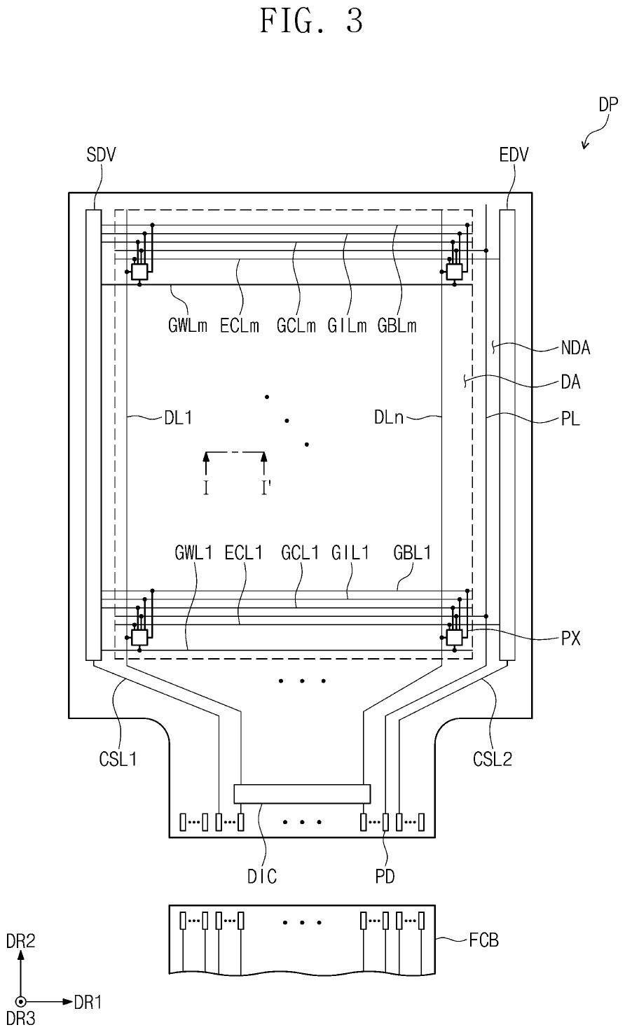

FIG. 3 illustrates a plan view showing the display panel DP according to an embodiment of the invention.

Referring to FIG. 3, an embodiment of the display panel DP may have a display region DA and a non-display region NDA around the display region DA. The display region DA and the non-display region NDA may be divided based on whether pixels PX are disposed or not. The pixels PX may be disposed on the display region DA and may not be disposed on the non-display region NDA.

The display panel DP may include the pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a driving voltage line PL, a scan driver SDV, a data driver, an emission driver EDV, a driver chip DIC, and pads PD. Here, “m” and “n” are natural numbers. The data driver may be a portion of circuits configured on the driver chip DIC.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 to electrically connect with the scan driver SDV. The data lines DL1 to DLn may extend in the second direction DR2 to electrically connect with the driver chip DIC. The emission control lines ECL1 to ECLm may extend in the first direction DR1 to electrically connect with the emission driver EDV.

The driving voltage line PL may include a part extending in the first direction DR1 and a part extending in the second direction DR2. The part extending in the first direction DR1 may be located at or disposed in a different layer from that of the part extending in the second direction DR2. The driving voltage line PL may provide with the pixels PX with a driving voltage.

The first control line CSL1 may be connected to the scan driver SDV. The second control line CSL2 may be connected to the emission driver EDV.

The driver chip DIC, the driving voltage line PL, the first control line CSL1, and the second control line CSL2 may be electrically connected to the pads PD. A flexible circuit film FCB may be electrically connected to the pads PD through an anisotropic conductive adhesion layer. The pads PD may connect the flexible circuit film FCB to the display panel DP. The pads PD may be connected to corresponding pixels PX through the driving voltage line PL, the first control line CSL1, and the second control line CSL2.

The pads PD may further include input pads. The input pads may connect the flexible circuit film FCB to the input sensor (see INS of FIG. 2). The invention, however, is not limited thereto, and the input pads may be disposed on the input sensor INS to connect with the pads PD and a separate circuit board. Alternatively, the input sensor INS may be omitted, and no input pads may be included.

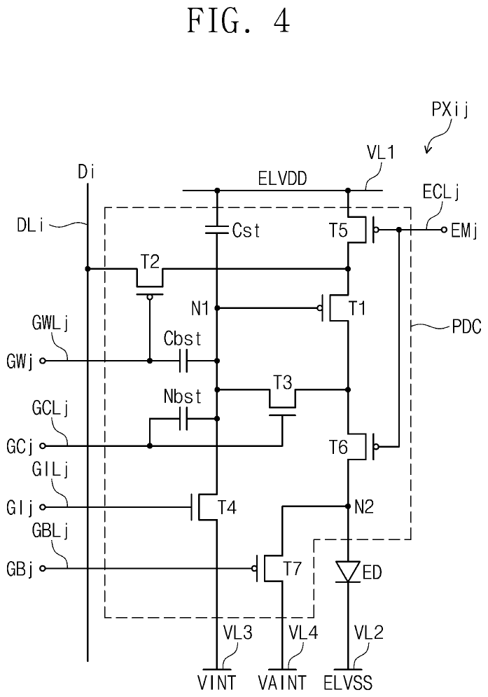

FIG. 4 illustrates an equivalent circuit diagram showing a pixel PXij according to an embodiment of the invention.

FIG. 4 illustrates an equivalent circuit diagram of one pixel PXij among a plurality of pixels (see PX of FIG. 3). The plurality of pixels PX may have a same circuit structure as each other, and thus the circuit structure of one pixel PXij will be described in detail below as a representative example of the pixels PX.

Referring to FIGS. 3 and 4, the pixel PXij may be coupled to an i^{th} data line DLi of the data lines DL1 to DLn, a j^{th} initialization scan line GILj of the initialization scan lines GIL1 to GILm, a j^{th} compensation scan line GCLj of the compensation scan lines GCL1 to GCLm, a j^{th} write scan line GWLj of the write scan lines GWL1 to GWLm, a j^{th} black scan line GBLj of the black scan lines GBL1 to GBLm, a j^{th} emission control line ECLj of the emission control lines ECL1 to EMLm, first and second driving voltage lines VL1 and VL2, and first and second initialization voltage lines VL3 and VL4. Here, i may be an integer between 1 and n, and the subscription j may be an integer between 1 and m.

The pixel PXij may include an emission element ED and a pixel circuit PDC. The emission element ED may be a light emitting diode. In an embodiment of the invention, the emission element ED may be an organic light emitting diode including an organic emission layer, but the invention is not particularly limited thereto. In response to a data signal Di, the pixel circuit PDC may control an amount of current flowing through the emission element ED. The emission element ED may emit light at a certain brightness level in response to an amount of current provided from the pixel circuit PDC.

The pixel circuit PDC may include first, second, third, fourth, fifth, sixth, and seventh transistors T1, T2, T3, T4, T5, T6, and T7 and first, second, and third capacitors Cst, Cbst, and Nbst. A configuration of the pixel circuit PDC according to the invention is not limited to the embodiment shown in FIG. 4. The pixel circuit PDC shown in FIG. 4 is merely an example, and the configuration of the pixel circuit PDC may be variously changed.

At least one of the first to seventh transistors T1 to T7 may be a transistor having a low-temperature polycrystalline silicon (LTPS) semiconductor layer. At least one of the first to seventh transistors T1 to T7 may be a transistor having an oxide semiconductor layer. In an embodiment, for example, the third and fourth transistors T3 and T4 may be oxide semiconductor transistors, and the first, second, fifth, sixth, and seventh T1, T2, T5, T6, and T7 may be LTPS transistors.

In an embodiment, for example, the first transistor T1 that directly affects brightness of the emission element ED may be configured to include a semiconductor layer including or formed of polycrystalline silicon having high reliability, which may result in achievement of a high-resolution display device. As an oxide semiconductor has high carrier mobility and low leakage current, there may be no large voltage drop even when a driving time is long. For example, a low-frequency operation may be possible because there is no large color change in image caused by voltage drop even in the low-frequency operation. Because an oxide semiconductor has a desired characteristic of low leakage current as discussed above, an oxide semiconductor may be adopted to form at least one of the third transistor T3 and the fourth transistor T4 that are connected to a gate electrode of the first transistor T1, such that it may be possible not only to prevent a leakage current that can be introduced to the gate electrode but also to reduce a consumption power.

One or more of the first to seventh transistors T1 to T7 may be p-type transistors, and remaining one or more of the first to seventh transistors T1 to T7 may be n-type transistors. In an embodiment, for example, the first, second, fifth, sixth, and seventh transistors T1, T2, T5, T6, and T7 may be p-type transistors, and the third and fourth transistors T3 and T4 may be n-type transistors.

The configuration of the pixel circuit PDC according to the invention is not limited to the embodiment depicted in FIG. 4. The pixel circuit PDC shown in FIG. 4 is merely an example, and the configuration of the pixel circuit PDC may be variously changed. In an embodiment, for example, all of the first to seventh transistors T1 to T7 may be p-type transistors or n-type transistors. In an embodiment, for example, the first, second, fifth, and sixth transistors T1, T2, T5, and T6 may be p-type transistors, and the third, fourth, and seventh transistors T3, T4, and T7 may be n-type transistors.

The j^{th} initialization scan line GILj, the j^{th} compensation scan line GCLj, the j^{th} write scan line GWLj, the j^{th} black scan line GBLj, and the j^{th} emission control line ECLj may provide the pixel PXij with a j^{th} initialization scan signal GIj, a j^{th} compensation scan signal GCj, a j^{th} write scan signal GWj, a j^{th} black scan signal GBj, and a j^{th} emission control signal EMj, respectively. The i^{th} data line DLi may transmit an i^{th} data signal Di to the pixel PXij. The i^{th} data signal Di may have a voltage level that corresponds to the image signal that is input to the display device (see DD of FIG. 1).

A first driving voltage ELVDD and a second driving voltage ELVSS may be transmitted to the pixel PXij through the first driving voltage line VL1 and the second driving voltage line VL2, respectively. In addition, a first initialization voltage VINT and a second initialization voltage VAINT may be transmitted to the pixel PXij through the first initialization voltage line VL3 and the second initialization voltage line VL4, respectively.

The first transistor T1 may be coupled between the emission element ED and the first driving voltage line VL1 to which the first driving voltage ELVDD is applied. The first transistor T1 may include a first electrode connected through the fifth transistor T5 to the first driving voltage line VL1, a second electrode connected through the sixth transistor T6 to a pixel electrode (or an anode) of the emission element ED, and a third electrode (e.g., a gate electrode) connected to an end (e.g., a first node N1) of the first capacitor Cst. The first transistor T1 may supply the emission element ED with a driving current by receiving the i^{th} data signal Di that is transmitted through the i^{th} data line DLi in accordance with a switching operation of the second transistor T2.

The second transistor T2 may be coupled between the i^{th} data line DLi and the first electrode of the first transistor T1. The second transistor T2 may include a first electrode connected to the i^{th} data line DLi, a second electrode connected to the first electrode of the first transistor T1, and a third electrode (e.g., a gate electrode) connected to the j^{th} write scan line GWLj. The second transistor T2 may be turned on with the j^{th} write scan signal GWj transmitted through the j^{th} write scan line GWLj, and may then provide the first electrode of the first transistor T1 with the i^{th} data signal Di transmitted from the i^{th} data line DLi. An end of the second capacitor Cbst may be connected to the third electrode of the second transistor T2, and another end of the second capacitor Cbst may be connected to the first node N1.

The third transistor T3 may be coupled between the first node N1 and the second electrode of the first transistor T1. The third transistor T3 may include a first electrode connected to the third electrode of the first transistor T1, a second electrode connected to the second electrode of the first transistor T1, and a third electrode (e.g., a gate electrode) connected to the j^{th} compensation scan line GCLj. The third transistor T3 may be turned on with the j^{th} compensation scan signal GCj transmitted through the j^{th} compensation scan line GCLj, and may then connect to each other the third and second electrodes of the first transistor T1 to thereby diode-connect the first transistor T1. An end of the third capacitor Nbst may be connected to the third electrode of the third transistor T3, and another end of the third capacitor Nbst may be connected to the first node N1.

The fourth transistor T4 may be coupled between the first node N1 and the first initialization voltage line VL3 to which the first initialization voltage VINT is applied. The fourth transistor T4 may include a first electrode connected to the first initialization voltage line VL3 through which the first initialization voltage VINT is transmitted, a second electrode connected to the first node N1, and a third electrode (e.g., a gate electrode) connected to the j^{th} initialization scan line GILj. The fourth transistor T4 may be turned on with the j^{th} initialization scan signal GIj transmitted through the j^{th} initialization scan line GILj. The turned-on fourth transistor T4 may provide the first node N1 with the first initialization voltage VINT to initialize a potential of the third electrode of the first transistor T1 (or a potential of the first node N1).

The fifth transistor T5 may include a first electrode connected to first driving voltage line VL1, a second electrode connected to the first electrode of the first transistor T1, and a third electrode (e.g., a gate electrode) connected to the j^{th} emission control line ECLj. The sixth transistor T6 may include a first electrode connected to the second electrode of the first transistor T1, a second electrode connected to the pixel electrode of the emission element ED, and a third electrode (e.g., a gate electrode) connected to the j^{th} emission control line ECLj.

The fifth and sixth transistors T5 and T6 may be simultaneously turned on with the j^{th} emission control signal EMj transmitted through the j^{th} emission control line ECLj. The first driving voltage ELVDD applied through the turned-on fifth transistor T5 may be compensated by the diode-connected first transistor T1 and may then be transmitted through the sixth transistor T6 to the emission element ED.

The seventh transistor T7 may include a first electrode connected to the second initialization voltage line VLA through which the second initialization voltage VAINT is transmitted, a second electrode connected to the second electrode of the sixth transistor T6, and a third electrode (e.g., a gate electrode) connected to the j^{th} black scan line GBLj. The second initialization voltage VAINT may have a voltage level the same as or less than that of the first initialization voltage VINT.

An end of the first capacitor Cst may be connected to the third electrode of the first transistor T1, and another end of the first capacitor Cst may be connected to the first driving voltage line VL1. A cathode of the emission element ED may be connected to the second driving voltage line VL2 through which the second driving voltage ELVSS is transmitted. The second driving voltage ELVSS may have a voltage level less than that of the first driving voltage ELVDD.

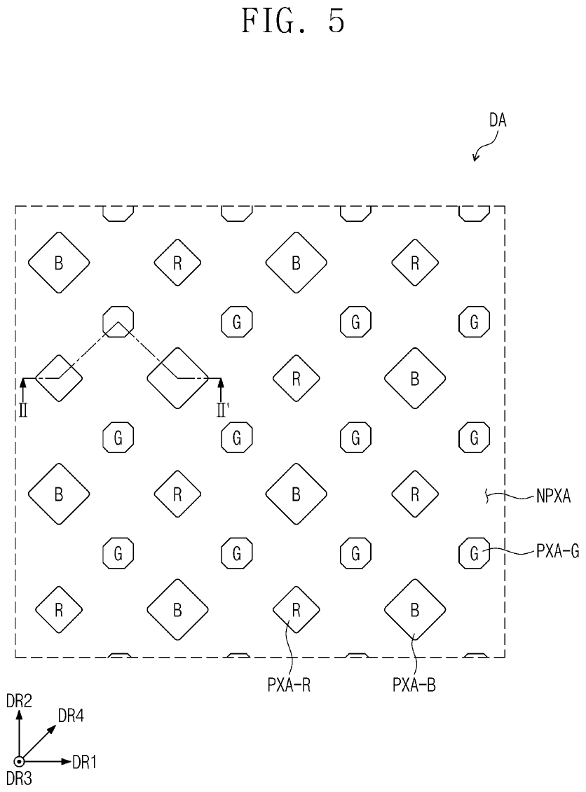

FIG. 5 illustrates an enlarged plan view partially showing the display region DA of the display panel (see DP of FIG. 2) according to an embodiment of the invention. FIG. 5 is a schematic plan view of a portion of the display module DM when viewed from above the display surface (see IS of FIG. 1B) of the display module (see DM of FIG. 1B), and shows an arrangement of emission regions PXA-R, PXA-G, and PXA-B.

Referring to FIG. 5, in an embodiment, the display region DA may include first, second, and third emission regions PXA-R, PXA-G, and PXA-B and a peripheral region NPXA that surrounds the first, second, and third emission regions PXA-R, PXA-G, and PXA-B. The first, second, and third emission regions PXA-R, PXA-G, and PXA-B may correspond to zones or planar areas through which rays of light provided from emission elements are emitted. The first, second, and third emission regions PXA-R, PXA-G, and PXA-B may be distinguished based on a color of light that is outwardly emitted from the display module (see DM of FIG. 2).

The first, second, and third emission regions PXA-R, PXA-G, and PXA-B may provide first color light, second color light, and third color light that have different colors from each other. For example, the first color light may be red light, the second color light may be green light, and the third color light may be blue light. However, the first color light, the second color light, and the third color light are not necessarily limited to the example mentioned above.

Each of the first, second, and third emission regions PXA-R, PXA-G, and PXA-B may be defined to correspond to a zone where a top surface of an anode is exposed by an emission opening which will be discussed below. The peripheral region NPXA may establish boundaries of the first, second, and third emission regions PXA-R, PXA-G, and PXA-B, and may effectively prevent a color mixing between the first, second, and third emission regions PXA-R, PXA-G, and PXA-B.

Each of the first, second, and third emission regions PXA-R, PXA-G, and PXA-B may be provided in plural, and on the display region DA, the plurality of first, second, and third emission regions PXA-R, PXA-G, and PXA-B may be repeatedly disposed while having a certain arrangement shape. In an embodiment, for example, the first and third emission regions PXA-R and PXA-B may be alternately arranged along the first direction DR1 to constitute a first group. The second emission regions PXA-G may be arranged along the first direction DR1 to constitute a second group. Each of the first group and the second group may be provided in plural, and the first groups and the second groups may be alternately arranged along the second direction DR2.

One second emission region PXA-G may be disposed spaced apart in a fourth direction DR4 from one first emission region PXA-R or one third emission region PXA-B. The fourth direction DR4 may be defined to correspond to a direction between the first and second directions DR1 and DR2.

FIG. 5 depicts an arrangement of the first, second, and third emission regions PXA-R, PXA-G, and PXA-B in an embodiment, but the invention is not limited thereto. In an embodiment, the first, second, and third emission regions PXA-R, PXA-G, and PXA-B may be arranged in a Pentile™ pattern as shown in FIG. 5. Alternatively, the first, second, and third emission regions PXA-R, PXA-G, and PXA-B may be arranged in a Stripe pattern or Diamond Pixel™ pattern.

The first, second, and third emission regions PXA-R, PXA-G, and PXA-B may have various shapes when viewed in plan. In an embodiment, for example, the first, second, and third emission regions PXA-R, PXA-G, and PXA-B may have a polygonal shape, a circular shape, or an oval shape. FIG. 5 shows an embodiment where the first and third emission regions PXA-R and PXA-B have a tetragonal or rhombic shape, and the second emission region PXA-G has an octagonal shape when viewed in plan.

When viewed in plan, the first, second, and third emission regions PXA-R, PXA-G, and PXA-B may have a same shape as each other, or one or more of the first, second, and third emission regions PXA-R, PXA-G, and PXA-B may have different shapes from each other. FIG. 5 shows an embodiment where the first and third emission regions PXA-R and PXA-B have a same shape as each other, and the second emission region PXA-G has a different shape from that of the first and third emission regions PXA-R and PXA-B when viewed in plan.

The first, second, and third emission regions PXA-R, PXA-G, and PXA-B may have various shapes when viewed in plan. In an embodiment, an area of the first emission region PXA-R from which red light is emitted may be greater than that of the second emission region PXA-G from which green light is emitted and less than that of the third emission region PXA-B from which blue light is emitted. The area size inequality between the first, second, and third emission regions PXA-R, PXA-G, and PXA-B in accordance with the color of light is not limited thereto, and may be variously changed depending on design of the display module (see DM of FIG. 2). The invention is not limited thereto, and the first, second, and third emission regions PXA-R, PXA-G, and PXA-B may have the same area when viewed in plan.

A shape, area, and arrangement of the first, second, and third emission regions PXA-R, PXA-G, and PXA-B of the display module (see DM of FIG. 2) according to an embodiment of the invention may be variously designed in accordance with a color of emitted light, a size of the display module (see DM of FIG. 2), and/or a configuration of the display module DM, and are not limited to the embodiment depicted in FIG. 5.

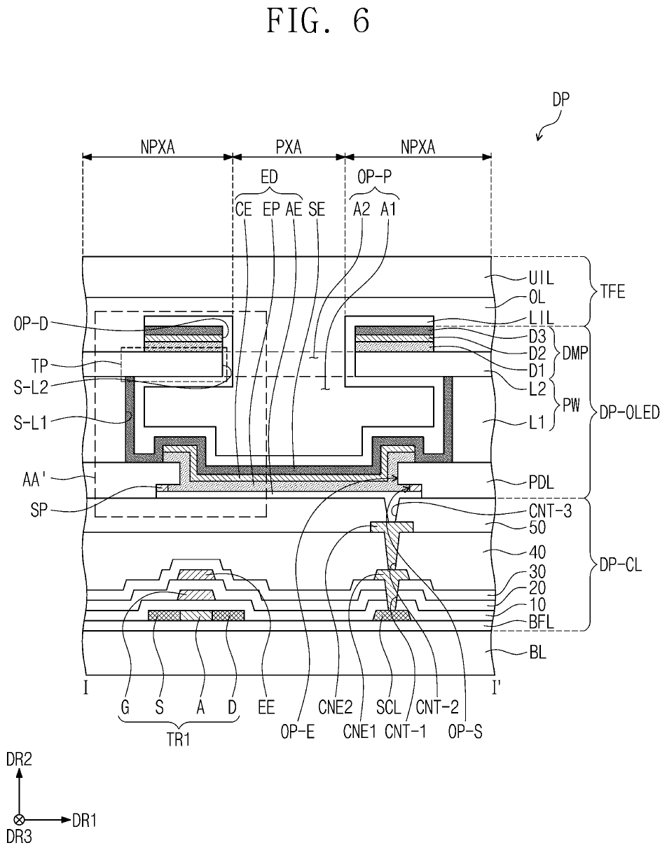

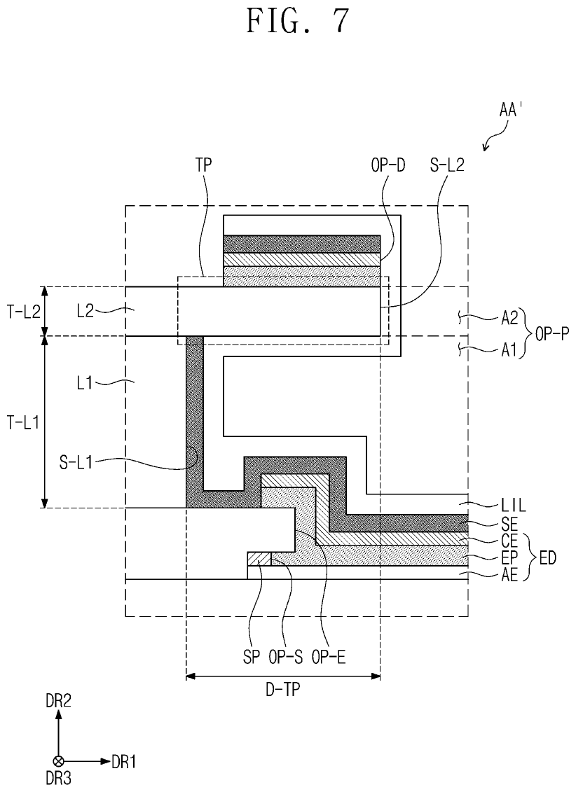

FIG. 6 illustrates a cross-sectional view taken along line I-I′ of FIG. 3, showing a display panel according to an embodiment of the invention. FIG. 7 illustrates an enlarged cross-sectional view of section AA′ of FIG. 6. Hereinafter, an embodiment of a display panel will be described with reference to FIGS. 6 and 7, together with FIG. 2, and the same reference numerals will be used to indicate the elements the same as those described above.

FIG. 6 is enlarged cross-sectional view showing an emission region PXA in the display region (see DA of FIG. 5), and the emission region PXA of FIG. 6 may correspond to one of the first, second, and third emission regions PXA-R, PXA-G, and PXA-B shown in FIG. 5. Referring to FIG. 6, an embodiment of the display panel DP may include a base layer BL, a circuit element layer DP-CL, a display element layer DP-OLED, and a thin encapsulation layer TFE.

The display panel DP may include a plurality of dielectric layers, a semiconductor pattern, a conductive pattern, and a signal line. In an embodiment, each dielectric layer, a semiconductor layer, and a conductive layer may be formed by coating and deposition. Afterwards, the dielectric layer, the semiconductor layer, and the conductive layer may be selectively patterned by photolithography and etching. The processes mentioned above may be performed to form the semiconductor pattern, the conductive pattern, and the signal line that are included in the circuit element layer DP-CL and the display element layer DP-OLED.

The circuit element layer DP-CL may be disposed on the base layer BL. The circuit element layer DP-CL may include a buffer layer BFL, a transistor TR1, a signal delivery section SCL, first to fifth dielectric layers 10, 20, 30, 40, and 50, an electrode EE, and a plurality of connection electrodes CNE1 and CNE2.

The buffer layer BFL may be disposed on the base layer BL. The buffer layer BFL may increase a bonding force between the base layer BL and a semiconductor pattern. In an embodiment, the buffer layer BFL may include a silicon oxide layer and a silicon nitride layer. In such an embodiment, the silicon oxide layer and the silicon nitride layer may be alternately stacked therein.

The semiconductor pattern may be disposed on the buffer layer BFL. The semiconductor pattern may include polysilicon. The invention, however, is not limited thereto, and the semiconductor pattern may include amorphous silicon or metal oxide. FIG. 6 illustrates an embodiment where a portion of the semiconductor pattern, and the semiconductor pattern may further be disposed on a plurality of emission regions (see PXA-R, PXA-G, and PXA-B of FIG. 5). The semiconductor pattern may be disposed at a specific rule across the plurality of emission regions PXA-R, PXA-G, and PXA-B. The semiconductor pattern may have different electrical properties based on whether the semiconductor pattern is doped or not. The semiconductor pattern may include a first section whose doping concentration is high and a second section whose doping concentration is low. The first section may be doped with n-type or p-type impurities.

The first section may have conductivity greater than that of the second section, and may substantially serve as an electrode or a signal line. The second section may substantially correspond to an active (or channel) of a transistor. In an embodiment, for example, a portion of the semiconductor pattern may be an active of a transistor, another portion of the semiconductor pattern may be a source or drain of a transistor, and a still another portion of the semiconductor pattern may be a conductive section.

The semiconductor pattern may define or be formed into a source S, an active A, and a drain D of the transistor TR1. FIG. 6 illustrates a portion of the signal delivery section SCL formed from the semiconductor pattern. Although not shown, when viewed in plan, the signal delivery section SCL may be connected to the drain D of the transistor TR1.

The first to fifth dielectric layers 10, 20, 30, 40, and 50 may be disposed on the buffer layer BFL. The first to fifth dielectric layers 10, 20, 30, 40, and 50 may be an inorganic layer or an organic layer.

The first dielectric layer 10 may be disposed on the buffer layer BFL. The first dielectric layer 10 may cover the signal delivery section SCL, and may also cover the source S, the active A, and drain D of the transistor TRI disposed on the buffer layer BFL. A gate G of the transistor TR1 may be disposed on the first dielectric layer 10. The second dielectric layer 20 may be disposed on the first dielectric layer 10 to cover the gate G. The electrode EE may be disposed on the second dielectric layer 20. The third dielectric layer 30 may be disposed on the second dielectric layer 20 to cover the electrode EE.

A first connection electrode CNE1 may be disposed on the third dielectric layer 30. The first connection electrode CNE1 may be coupled to the signal delivery section SCL through a contact hole CNT-1 defined through the first, second, and third dielectric layers 10, 20, and 30. The fourth dielectric layer 40 may be disposed on the third dielectric layer 30 to cover the first connection electrode CNE1. The fourth dielectric layer 40 may be an organic layer.

A second connection electrode CNE2 may be disposed on the fourth dielectric layer 40. The second connection electrode CNE2 may be coupled to the first connection electrode CNE1 through a contact hole CNT-2 defined through the fourth dielectric layer 40. The fourth dielectric layer 40 may be provided thereon with the fifth dielectric layer 50 that covers the second connection electrode CNE2. The fifth dielectric layer 50 may be an organic layer.

The display element layer DP-OLED may be disposed on the circuit element layer DP-CL. The display element layer DP-OLED may include an emission element ED, a sacrificial pattern SP, a pixel definition layer PDL, a partition wall PW, a subsidiary electrode SE, and dummy patterns DMP.

The emission element ED may include an anode AE (or a first electrode), an emission pattern EP, and a cathode CE (or a second electrode).

The anode AE may be disposed on the fifth dielectric layer 50 of the circuit element layer DP-CL. The anode AE may be a transmissive electrode, a transflective electrode, or a reflective electrode. The anode AE may be coupled to the second connection electrode CNE2 through a coupling contact hole CNT-3 defined through the fifth dielectric layer 50. Therefore, the anode AE may be electrically connected to the signal delivery section SCL through the first and second connection electrodes CNE1 and CNE2, and may be electrically connected to a corresponding circuit element. The anode AE may have a single-layered or multi-layered structure. The anode AE may include a plurality of layers including indium tin oxide (ITO) and silver (Ag). In an embodiment, for example, the anode AE may include an ITO-containing layer (or a lower ITO layer), an Ag-containing layer (or an Ag layer) disposed on the lower ITO layer, and an ITO-containing layer (or an upper ITO layer) disposed on the Ag layer, that is, ITO/Ag/ITO structure.

The sacrificial pattern SP may be disposed between the anode AE and the pixel definition layer PDL. The sacrificial pattern SP may include a sacrificial opening OP-S that partially exposes a top surface of the anode AE. The sacrificial opening OP-S may overlap an emission opening OP-E which will be described later.

The pixel definition layer PDL may be disposed on the base layer BL. In an embodiment, for example, the pixel definition layer PDL may be disposed on the fifth dielectric layer 50 of the circuit element layer DP-CL. An emission opening OP-E may be defined in the pixel definition layer PDL. The emission opening OP-E may correspond to the anode AE, and the at least a portion of the anode AE may be exposed by the emission opening OP-E of the pixel definition layer PDL.

In addition, the emission opening OP-E may correspond to the sacrificial opening OP-S of the sacrificial pattern SP. According to an embodiment of the invention, when viewed in vertical section, the top surface of the anode AE may be spaced apart from the pixel definition layer PDL across the sacrificial pattern SP, and thus the anode AE may be protected against damage in a process for forming the emission opening OP-E.

When viewed in plan, an area of the emission opening OP-E may be less than that of the sacrificial opening OP-S. In an embodiment, for example, an inner lateral surface of the pixel definition layer PDL that defines the emission opening OP-E may be closer to a center of the anode AE than an inner lateral surface of the sacrificial pattern SP that defines the sacrificial opening OP-S. The invention, however, is not limited thereto, and the inner lateral surface of the pixel definition layer PDL that defines the emission opening OP-E may be substantially aligned with the inner lateral surface of the sacrificial pattern SP that defines the sacrificial opening OP-S.

The pixel definition layer PDL may include an inorganic dielectric material. In an embodiment, for example, the pixel definition layer PDL may include silicon nitride (SiNx). The pixel definition layer PDL may be disposed between the anode AE and the partition wall PW to prevent an electrical connection between the anode AE and the partition wall PW.

The partition wall PW may be disposed on the pixel definition layer PDL. A partition opening OP-P may be defined in the partition wall PW. The partition opening OP-P may overlap the emission opening OP-E and may expose at least a portion of the anode AE.

The partition wall PW may have an undercut shape when viewed in cross section. The partition wall PW may include a plurality of sequentially stacked layers, and at least one of the layers may be more recessed (or more protruding toward a center of the emission region PXA) than other layers when viewed in plane. In such an embodiment, the partition wall PW may include a tip TP.

The partition wall PW may include a first partition layer L1 and a second partition layer L2. The first partition layer L1 may be disposed on the pixel definition layer PDL, and the second partition layer L2 may be disposed on the first partition layer L1. In an embodiment, as shown in FIG. 6, a thickness of the first partition layer L1 may be greater than that of the second partition layer L2, but the invention is not limited thereto.

In such an embodiment, the first partition layer L1 may be relatively recessed with respect to the emission region PXA compared to the second partition layer L2. The first partition layer L1 may be undercut with respect to the second partition layer L2. The second partition layer L2 may have a portion that protrudes from the first partition layer L1 toward the center of the emission region PXA, and the protruding portion of the second partition layer L2 may be defined as the tip TP of the partition wall PW. In an embodiment, for example, the second partition layer L2 may include the tip TP that protrudes from the first partition layer L1 toward a center of the partition opening OP-P.

Referring to FIGS. 6 and 7, the tip TP may have a length D-TP in the first direction DR1, and the length D-TP may be a length between a first inner lateral surface S-L1 of the first partition layer L1 that defines the partition opening OP-P and a second inner lateral surface S-L2 of the second partition layer L2 that defines the partition opening OP-P. The length D-TP in the first direction DR1 of the tip TP may be equal to or greater than about 1.5 times a thickness T-L1 of the first partition layer L1. According to an embodiment of the invention, as the length D-TP in the first direction DR1 of the tip TP is equal to or greater than about 1.5 times the thickness T-LI of the first partition layer L1, neither the emission pattern EP nor the cathode CE may be formed to contact the partition wall PW. In an embodiment, for example, when viewed in plan, the emission pattern EP and the cathode CE may be formed spaced apart from the first inner lateral surface S-L1 of the first partition layer L1. In addition, a thickness T-L2 of the second partition layer L2 may be in a range from about 2,000 angstrom (Å) to about 3,000 Å. As the thickness T-L2 of the second partition layer L2 is relatively large, the tip TP may maintain its shape.

Referring back to FIG. 6, the partition opening OP-P defined in the partition wall PW may include a first region A1 and a second region A2. The first partition layer L1 may include the first inner lateral surface S-L1 that defines the first region A1 of the partition opening OP-P, and the second partition layer L2 may include the second inner lateral surface S-L2 that defines the second region A2 of the partition opening OP-P. When viewed in cross section, the second inner lateral surface S-L2 of the second partition layer L2 may be closer to a center of the anode AE than the first inner lateral surface S-L1 of the first partition layer L1. Compared to the second inner lateral surface S-L2, the first inner lateral surface S-L1 may be recessed in a direction away from the center of the anode AE.

A width of the first region A1 may be different from that of the second region A2. The width of the first region A1 may be greater than that of the second region A2. In this case, the second region A2 of the partition opening OP-P may be a region (zone or area) that defines the tip TP. The emission region PXA may correspond to be a portion of the anode AE exposed through the second region A2 of the partition wall PW that corresponds thereto.

Each of the first partition layer L1 and the second partition layer L2 may include a conductive material. In an embodiment, for example, the conductive material may include metal, transparent conductive oxide (TCO), or any combination thereof. In an embodiment, for example, the metal may include gold (Au), silver (Sg), aluminum (Al), magnesium (Mg), lithium (Li), molybdenum (Mo), titanium (Ti), copper (Cu), or any alloy thereof. The transparent conductive oxide may include indium tin oxide (ITO), indium zinc oxide (IZO), zinc oxide (ZnO), indium oxide (InO), indium gallium oxide (IGO), indium gallium zinc oxide (IGZO), or aluminum zinc oxide (AZO).

FIG. 6 illustrates an embodiment where each of the first and second inner lateral surfaces S-L1 and S-L2 is perpendicular to a top surface of the pixel definition layer PDL, but the invention is not limited thereto. In an embodiment, for example, the partition wall PW may have a tapered shape or a inversely tapered shape.

The emission pattern EP may be disposed on the anode AE. The emission pattern EP may include an emission layer including a light emitting material. The emission pattern EP may further include a hole injection layer (HIL) and a hole transport layer (HTL) disposed between the anode AE and the emission layer, and may further include an electron transport layer (ETL) and an electron injection layer (EIL) disposed on the emission layer. The emission pattern EP may be called an organic layer or an intermediate layer.

The emission pattern EP may be patterned by the tip TP of the partition wall PW. The emission pattern EP may be disposed inside the sacrificial opening OP-S, the emission opening OP-E, and the partition opening OP-P. The emission pattern EP may be deposited on a portion of the top surface of the pixel definition layer PDL exposed through the partition opening OP-P. In an embodiment, for example, an end (e.g., both ends) of the emission pattern EP may be formed on the top surface of the pixel definition layer PDL. When viewed in plan, the emission pattern EP may be spaced apart from a lateral surface of the partition wall PW. In an embodiment, for example, when viewed in plan, the emission pattern EP may be spaced apart from the first inner lateral surface S-L1 of the first partition layer L1. In such an embodiment, the emission pattern EP may not be in contact with the partition wall PW.

A p-doped one of the hole injection layer included in the emission pattern EP may have conductivity. In this case, if the emission pattern EP is formed in contact with the partition wall PW, the partition wall PW including a conductive material and the emission pattern EP may be electrically connected to each other such that a leakage current may be generated. According to an embodiment of the invention, as the emission pattern EP and the partition wall PW are spaced apart from each other when viewed in plan, even when a portion (e.g., the p-doped hole injection layer) of the emission pattern EP has conductivity, the occurrence of such leakage current may be effectively prevented.

The cathode CE may be disposed on the emission pattern EP. The cathode CE may be patterned or disconnected by the tip TP of the partition wall PW. At least a portion of the cathode CE may be disposed in the partition opening OP-P. The cathode CE may be deposited on a portion of the top surface of the pixel definition layer PDL exposed through the partition opening OP-P. In an embodiment, for example, an end (e.g., both ends) of the cathode CE may be formed on the pixel definition layer PDL. When viewed in plan, the cathode CE may be spaced apart from the lateral surface of the partition wall PW. In an embodiment, for example, when viewed in plan, the cathode CE may be spaced apart from the first inner lateral surface S-L1 of the first partition layer L1. Therefore, in such an embodiment, the cathode CE may not be in contact with the partition wall PW.

The cathode CE may have conductivity. The cathode CE may include or be formed of any material as long as the material has conductivity, such as transparent conductive oxide (TCO) or conductive polymer materials. In an embodiment, for example, the cathode CE may include silver (Ag), magnesium (Mg), lead (Pb), copper (Cu), or any compound thereof.

A relatively small bonding force may be provided between the cathode CE and the partition wall PW. According to the invention, as the cathode CE is formed on the pixel definition layer PDL without being in contact with the partition wall PW and is electrically connected to the partition wall PW through the subsidiary electrode SE which will be discussed below, there may be a reduction or elimination in contact failure between the cathode CE and the partition wall PW.

FIG. 6 shows an embodiment where an end of the emission pattern EP is vertically aligned with an end of the cathode CE, but the invention is not limited thereto. In an embodiment, for example, the end of the cathode CE may cover the end of the emission pattern EP.

The subsidiary electrode SE may be disposed on the emission element ED. In an embodiment, for example, the subsidiary electrode SE may be disposed on the cathode CE. A portion of the subsidiary electrode SE may be disposed on the partition opening OP-P. The subsidiary electrode SE may extend along the first inner lateral surface S-L1 of the first partition layer L1. In an embodiment, for example, the subsidiary electrode SE may extend while being in contact with the first inner lateral surface S-L1 of the first partition layer L1. The subsidiary electrode SE may cover an end (e.g., both ends) of the emission pattern EP and an end (e.g., both ends) of the cathode CE.

The subsidiary electrode SE may be in contact with the cathode CE and the first inner lateral surface S-L1 of the first partition layer L1. In an embodiment, for example, the subsidiary electrode SE may be electrically connected to the partition wall PW and the cathode CE. The partition wall PW may receive the second driving voltage (see ELVSS of FIG. 3B), and the subsidiary electrode SE may be electrically coupled to the partition wall PW to receive the second driving voltage ELVSS. Therefore, the cathode CE electrically connected to the subsidiary electrode SE may receive the second driving voltage ELVSS.

The subsidiary electrode SE may have conductivity. In an embodiment, for example, the subsidiary electrode SE may include titanium nitride (TiN). According to an embodiment of the invention, the cathode CE may be electrically connected through the subsidiary electrode SE to the partition wall PW, without being in direct contact with partition wall PW. A bonding force between the subsidiary electrode SE and the cathode CE and a bonding force between the subsidiary electrode SE and the partition wall PW may be greater than a bonding force between the cathode CE and the partition wall PW. Accordingly, in such an embodiment, delamination of the cathode CE in contact with the partition wall PW may be effectively prevented such that foreign substances may be effectively prevented from being introduced into the display element layer DP-OLED. In such an embodiment, as the subsidiary electrodes SE including titanium nitride (TiN) has a high resistance to chemicals, the display element layer DP-OLED may have improved durability and the display panel DP may have an increased life span.

In another embodiment of the invention, the subsidiary electrode SE may include transparent conductive oxide (TCO). In an embodiment, for example, the subsidiary electrode SE may include indium tin oxide (ITO) or indium zinc oxide (IZO). The invention, however, is not limited thereto, and the subsidiary electrode SE may include or be formed of any material as long as the material has conductivity, such as a conductive polymer material.

The display element layer DP-OLED may further include a capping pattern (not shown). The capping pattern may be disposed in the partition opening OP-P. The capping pattern may be disposed on the cathode CE or the subsidiary electrode SE. The capping pattern may be patterned by the tip TP of the partition wall PW.

The dummy patterns DMP may be disposed on the partition wall PW. The dummy patterns DMP may include a first dummy pattern D1, a second dummy pattern D2, and a third dummy pattern D3. The first, second, and third dummy patterns D1, D2, and D3 may be sequentially stacked along the third direction DR3 on a top surface of the second partition layer L2 of the partition wall PW.

The first dummy pattern D1 may include an organic material. In an embodiment, for example, the first dummy pattern D1 may include a same material as that of the emission pattern EP. The first dummy pattern D1 and the emission pattern EP may be simultaneously formed in a same process, and the undercut shape of the partition wall PW may cause the first dummy pattern D1 to be formed separately from the emission pattern EP.

The second dummy pattern D2 may include a conductive material. In an embodiment, for example, the second dummy pattern D2 may include a same material as that of the cathode CE. The second dummy pattern D2 and the cathode CE may be simultaneously formed in a same process, and the undercut shape of the partition wall PW may cause the second dummy pattern D2 to be formed separately from the cathode CE.

The third dummy pattern D3 may include a conductive material. For example, the third dummy pattern D3 may include a same material as that of the subsidiary electrode SE. The third dummy pattern D3 and the subsidiary electrode SE may be simultaneously formed in a same process, and the undercut shape of the partition wall PW may cause the third dummy pattern D3 to be formed separately from the subsidiary electrode SE.

In an embodiment where the display element layer DP-OLED further includes the capping pattern, the dummy patterns DMP may further include a fourth dummy pattern (not shown). The fourth dummy pattern may include a conductive material. In an embodiment, for example, the fourth dummy pattern may include a same material as that of the capping pattern. The fourth dummy pattern and the capping pattern may be simultaneously formed in a same process, and the undercut shape of the partition wall PW may cause the fourth dummy pattern to be formed separately from the capping pattern.

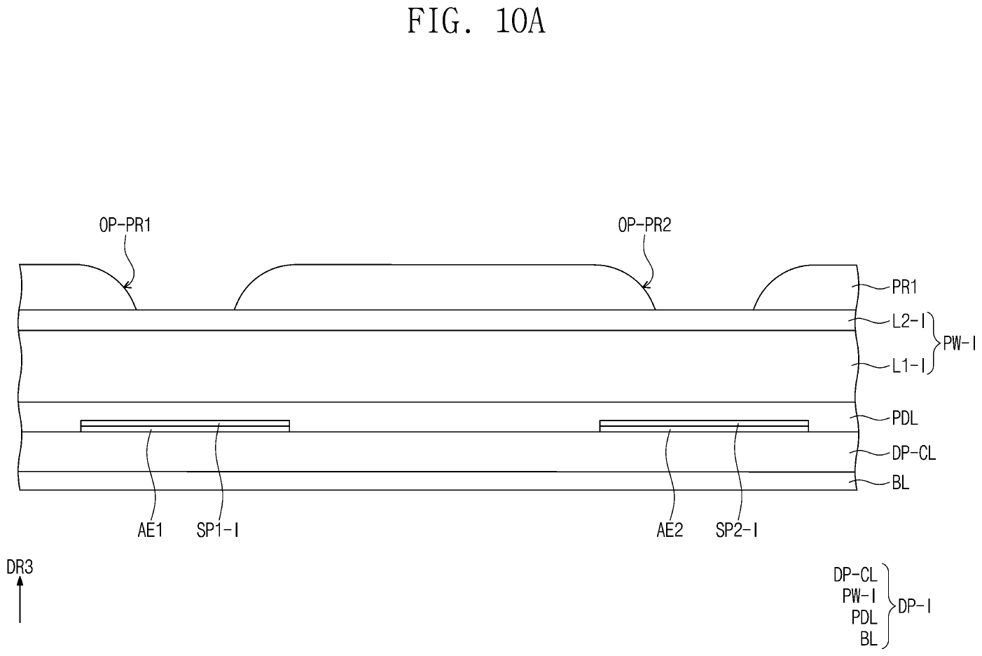

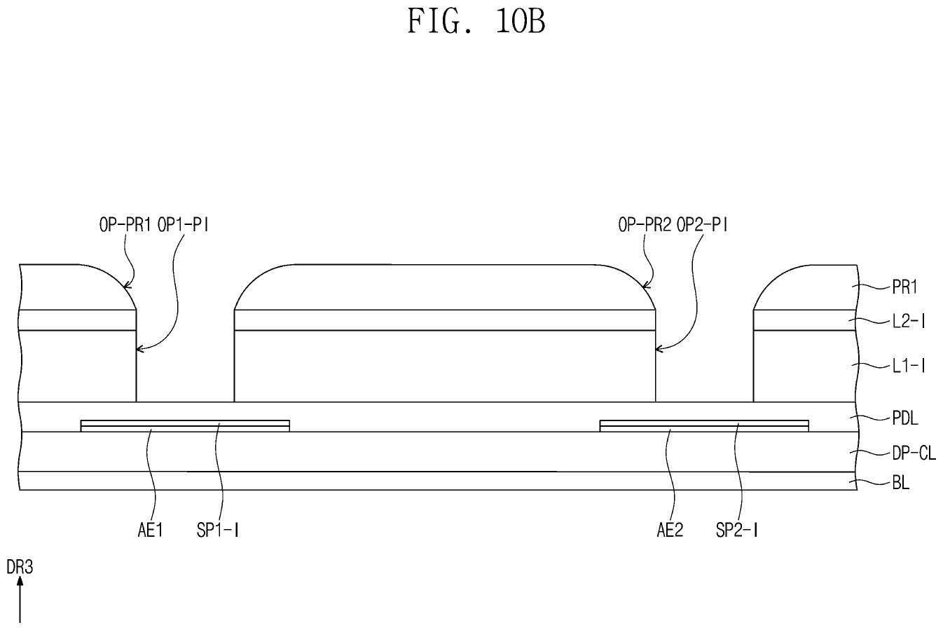

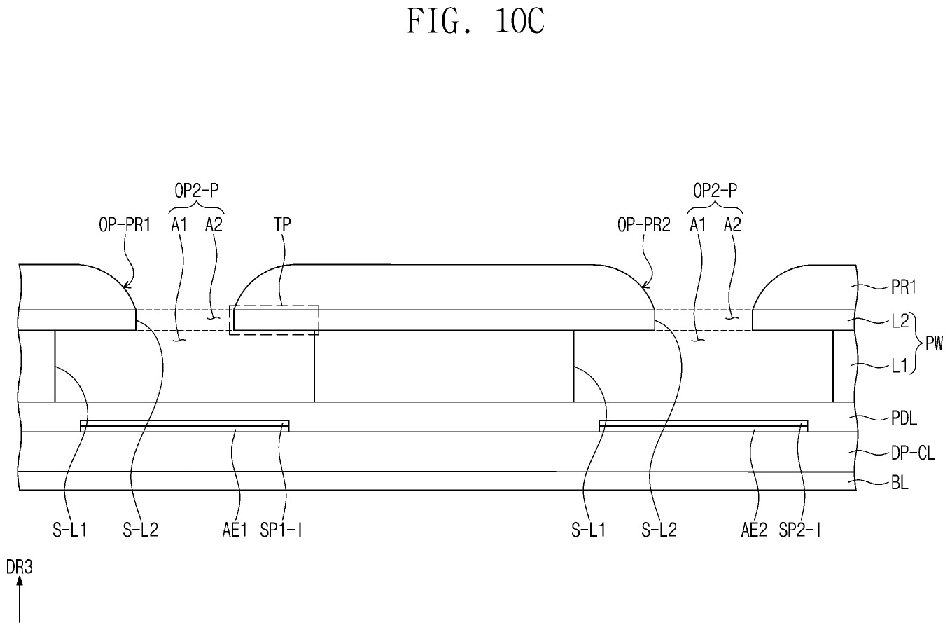

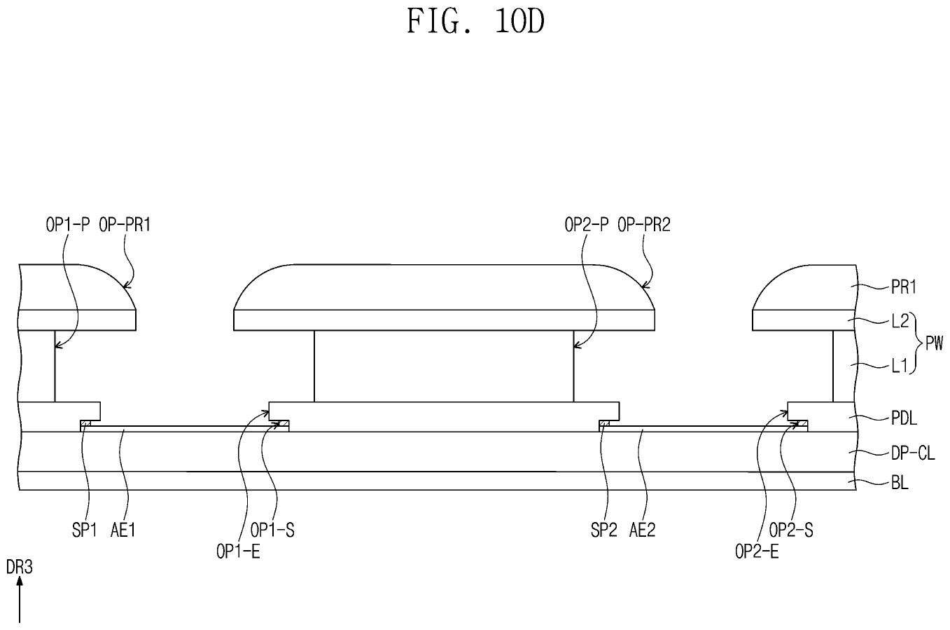

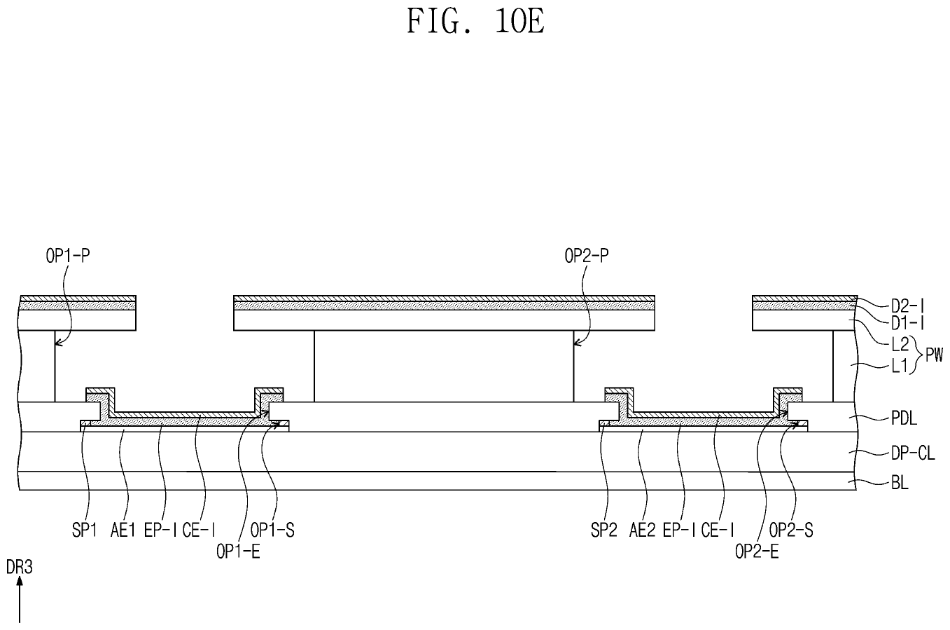

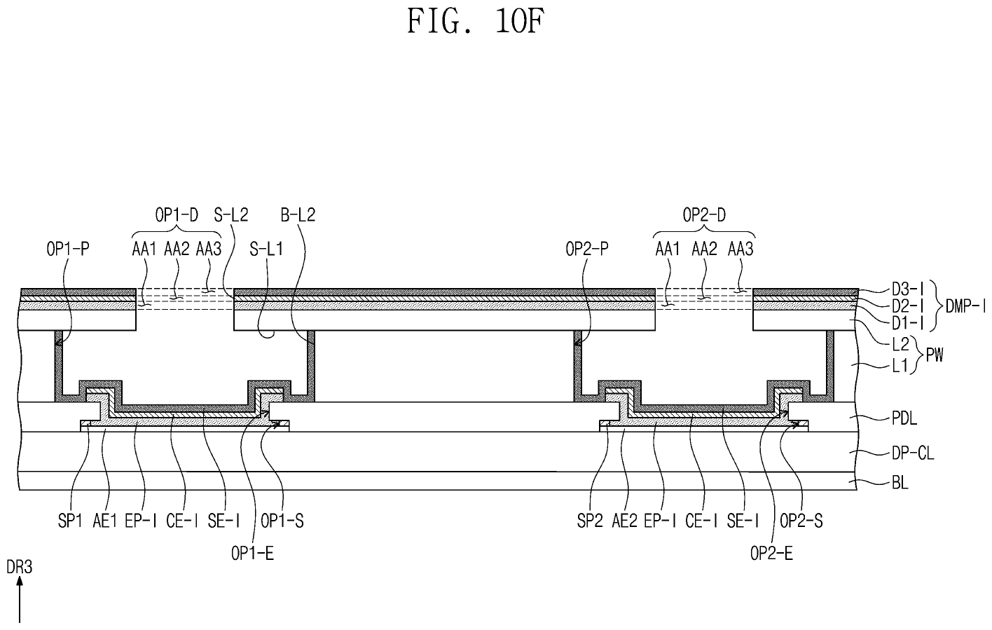

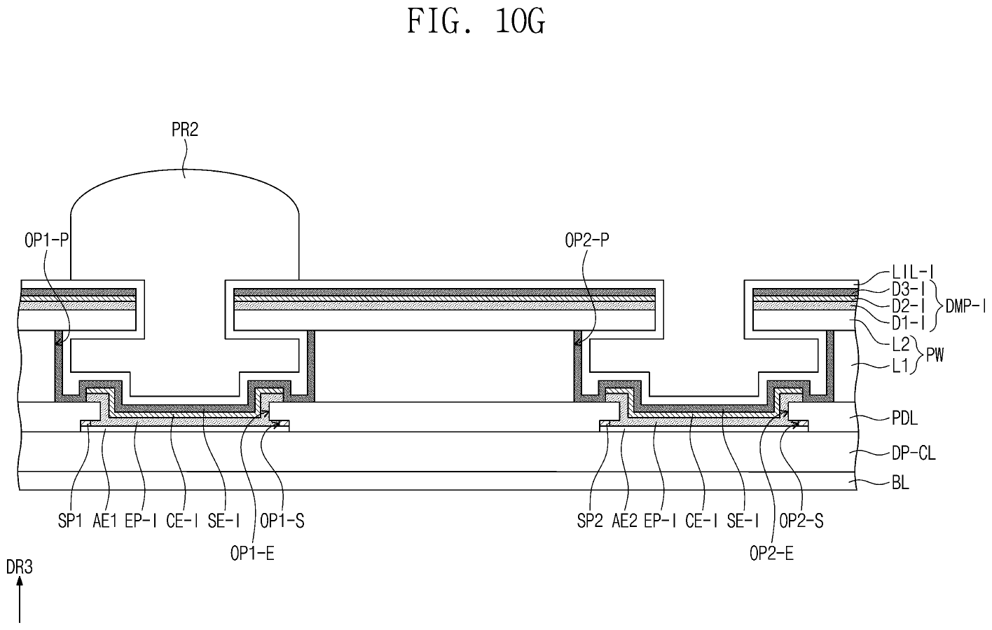

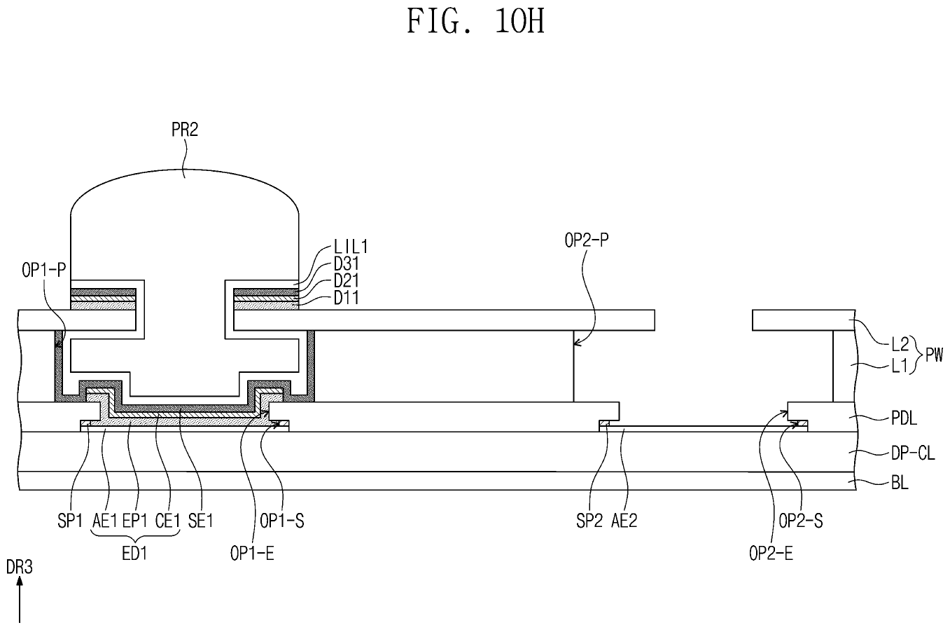

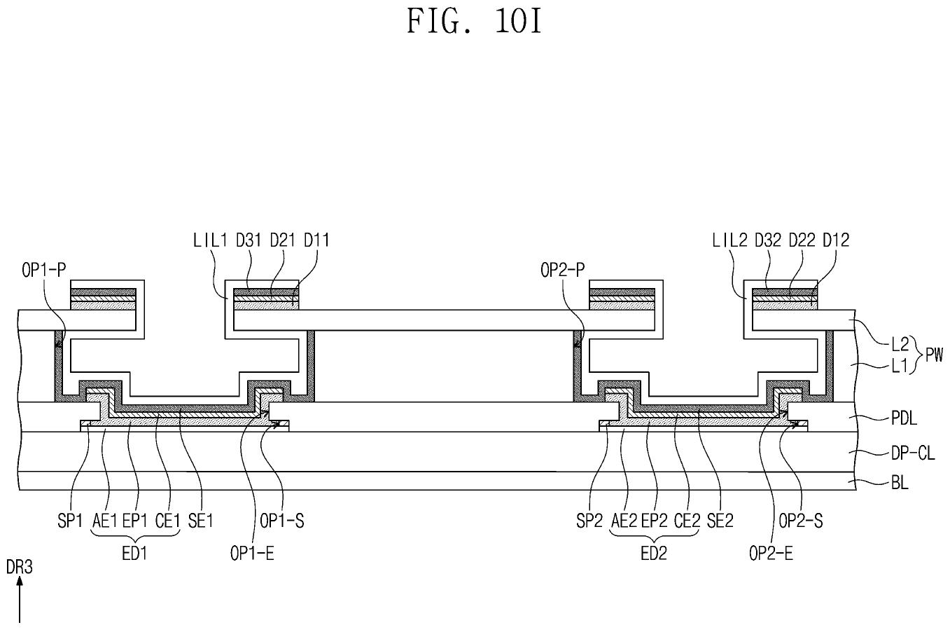

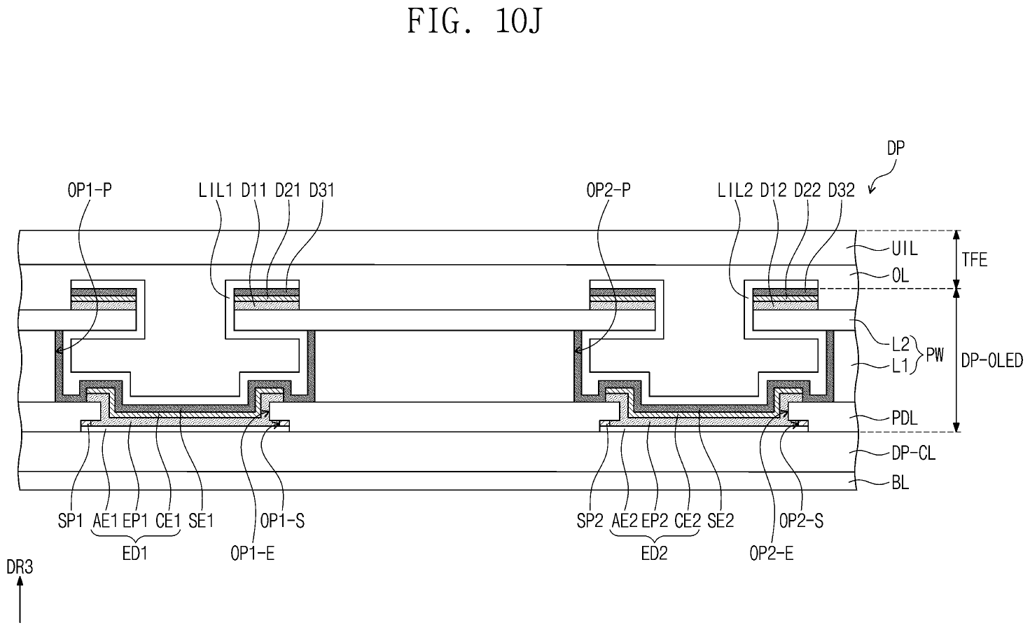

A dummy opening OP-D may be defined in the dummy patterns DMP. The dummy opening OP-D may overlap the emission opening OP-E. The dummy opening OP-D may include first, second, and third regions that are sequentially arranged in the third direction DR3. The first region (see AA1 of FIG. 10F) of the dummy opening OP-D may be defined by an inner lateral surface of the first dummy pattern D1, the second region (see AA2 of FIG. 10F) may be defined by an inner lateral surface of the second dummy pattern D2, and the third region (see AA3 of FIG. 10F) may be defined by an inner lateral surface of the third dummy pattern D3. When viewed in plan, each of the first, second, and third dummy patterns D1, D2, and D3 may have a closed line shape that surrounds the emission region PXA.

Although FIG. 6 shows an embodiment where the inner lateral surfaces of the first, second, and third dummy patterns D1, D2, and D3 are vertically aligned with the second inner lateral surface S-L2 of the second partition layer L2, the invention is not limited thereto and the first, second, and third dummy patterns D1, D2, and D3 may cover the second inner lateral surface S-L2.

The thin encapsulation layer TFE may be disposed on the display element layer DP-OLED. The thin encapsulation layer TFE may include a lower encapsulation inorganic pattern LIL, an encapsulation organic layer OL, and an upper encapsulation inorganic layer UIL.

The lower encapsulation inorganic pattern LIL may be disposed on the subsidiary electrode SE. The lower encapsulation inorganic pattern LIL may be formed corresponding to the emission opening OP-E. The lower encapsulation inorganic pattern LIL may be in direct contact with the subsidiary electrode SE. in an embodiment, for example, a portion of the lower encapsulation inorganic pattern LIL may cover the subsidiary electrode SE in the partition opening OP-P.

The encapsulation organic layer OL may provide a flat top surface while covering the lower encapsulation inorganic pattern LIL. The upper encapsulation inorganic layer UIL may be disposed on the encapsulation organic layer OL.

The lower encapsulation inorganic pattern LIL and the upper encapsulation inorganic layer UIL may protect the display element layer DP-OLED against moisture and/or oxygen, and the encapsulation organic layer OL may protect the display element layer DP-OLED against foreign substances such as dust particles.

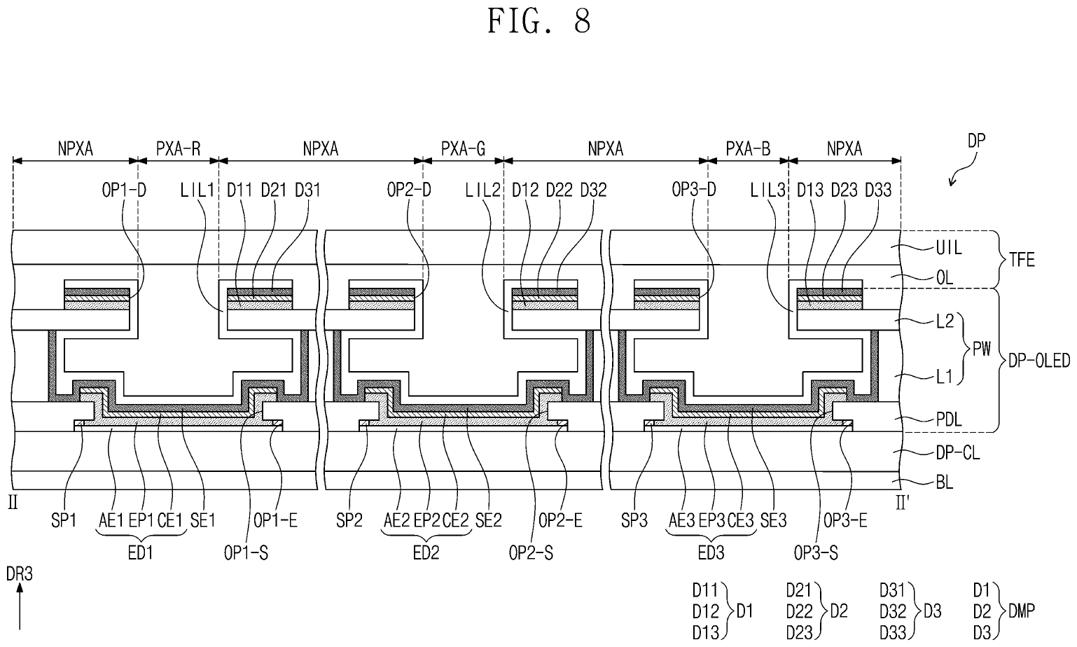

FIG. 8 illustrates a cross-sectional view taken along line II-II′ of FIG. 5. FIG. 8 shows an enlarged cross-sectional view showing one first emission region PXA-R, one second emission region PXA-G, and one third emission region PXA-B, and each of the first, second, and third emission regions PXA-R, PXA-G, and PXA-B may correspond to the emission region PXA described above with reference to FIG. 6.

Referring to FIG. 8, the display panel DP according to an embodiment of the invention may include a base layer BL, a circuit element layer DP-CL, a display element layer DP-OLED, and a thin encapsulation layer TFE. The display element layer DP-OLED may include emission elements ED1, ED2, and ED3, sacrificial patterns SP1, SP2, and SP3, a pixel definition layer PDL, a partition wall PW, subsidiary electrodes SE1, SE2, and SE3, and dummy patterns DMP.

The emission elements ED1, ED2, and ED3 may include a first emission element ED1, a second emission element ED2, and a third emission element ED3. The first emission element ED1 may include a first anode AE1, a first emission pattern EP1, and a first cathode CE1. The second emission element ED2 may include a second anode AE2, a second emission pattern EP2, and a second cathode CE2. The third emission element ED3 may include a third anode AE3, a third emission pattern EP3, and a third cathode CE3. The first, second, and third anodes AE1, AE2, and AE3 may be provided as (or defined by) a plurality of patterns. In an embodiment, the first emission pattern EP1 may emit red light, the second emission pattern EP2 may emit green light, and the third emission pattern EP3 may emit blue light.

The pixel definition layer PDL may be provided with first, second, and third emission openings OP1-E, OP2-E, and OP3-E that are defined therethrough. The first emission opening OP1-E may expose at least a portion of the first anode AE1. The second emission opening OP2-E may expose at least a portion of the second anode AE2. The third emission opening OP3-E may expose at least a portion of the third anode AE3.

The sacrificial patterns SP1, SP2, and SP3 may include a first sacrificial pattern SP1, a second sacrificial pattern SP2, and a third sacrificial pattern SP3. The first, second, and third sacrificial patterns SP1, SP2, and SP3 may be disposed on top surfaces of the first, second, and third anodes AE1, AE2, and AE3, respectively. The first, second, and third sacrificial patterns SP1, SP2, and SP3 may respectively be provided with first, second, and third sacrificial openings OP1-S, OP2-S, and OP3-S defined therethrough to respectively overlap the first, second, and third emission openings OP1-E, OP2-E, and OP3-E.

In an embodiment, the partition wall PW may be provided with first, second, and third partition openings OP1-P, OP2-P, and OP3-P defined therethrough to respectively overlap the first, second, and third emission openings OP1-E, OP2-E, and OP3-E. The first emission region PXA-R may be defined to correspond to a zone where the top surface of the first anode AE1 is exposed by the first partition opening OP1-P. The second emission region PXA-G may be defined to correspond to a zone where the top surface of the second anode AE2 is exposed by the second partition opening OP2-P. The third emission region PXA-B may be defined to correspond to a zone where the top surface of the third anode AE3 is exposed by the third partition opening OP3-P.

Each of the first, second, and third partition openings OP1-P, OP2-P, and OP3-P may include a first region (see A1 of FIG. 6) and a second region (see A2 of FIG. 6). A first partition layer L1 may include first inner lateral surfaces (see S-L1 of FIG. 6) that define the first regions A1 of the first, second, and third partition openings OP1-P, OP2-P, and OP3-P, and a second partition layer L2 may include second inner lateral surfaces (see S-L2 of FIG. 6) that define the second regions A2 of the first, second, and third partition openings OP1-P, OP2-P, and OP3-P.

The first emission pattern EP1 and the first cathode CE1 may be disposed in the first partition opening OP1-P, the second emission pattern EP2 and the second cathode CE2 may be disposed in the second partition opening OP2-P, and the third emission pattern EP3 and the third cathode CE3 may be disposed in the third partition opening OP3-P.

In an embodiment, the first, second, and third emission patterns EP1, EP2, and EP3 and the first, second, and third cathodes CE1, CE2, and CE3 may be physically divided by the second partition layer L2 that forms a tip, and may be formed in the emission openings OP1-E, OP2-E, and OP3-E and the first, second, and third partition openings OP1-P, OP2-P, and OP3-P. When viewed in plan, the first, second, and third emission patterns EP1, EP2, and EP3 and the first, second, and third cathodes CE1, CE2, and CE3 may each be spaced apart from the partition wall PW. In an embodiment, for example, each of the first, second, and third emission patterns EP1, EP2, and EP3 and the first, second, and third cathodes CE1, CE2, and CE3 may not be in contact with the first inner lateral surface S-L1 of the first partition layer L1.

According to an embodiment of the invention, a plurality of first emission patterns EP1 may be deposited and patterned for each pixel unit by the tip of the partition wall PW. In an embodiment, for example, the first emission patterns EP1 may be formed in common by using an open mask, and may be easily divided for each pixel unit by the partition wall PW.

In a case where a fine metal mask (FMM) is used to pattern the first emission patterns EP1, the fine metal mask may be desired to be supported by a support spacer that protrudes from a conductive partition wall. In this case, as the fine metal mask is spaced apart at a height of the partition wall and the spacer from a base surface where patterning is performed, a limitation may be imposed on achievement of high resolution. Moreover, as the fine metal mask is in contact with the spacer, foreign substances may remain on the spacer after the first emission patterns EPI are patterned, or the spacer may be damaged due to a scratch from the fine metal mask. Therefore, a defective display panel may be formed in this case.

According to an embodiment of the embodiment, the partition wall PW may be included such that a physical separation of the emission elements ED1, ED2, and ED3 may be easily implemented. Accordingly, a leakage current or an operating error between neighboring emission regions PXA-R, PXA-G, and PXA-B may be effectively prevented such that each of the emission elements ED1, ED2, and ED3 may be allowed to effectively operate independently of each other.

In such an embodiment, as a plurality of first emission patterns EP1 are patterned without a mask in contact with an inner component of the display region (see DA of FIG. 1B), a failure rate may decrease such that process reliability of the display panel DP may be increased. In such an embodiment, no support spacer is separately provided which protrudes from the partition wall PW, such that areas of the emission regions PXA-R, PXA-G, and PXA-B may be reduced to allow the display panel DP to be configured to have high resolution.

In an embodiment, the display panel DP is a large-sized display panel, the a process using a large-sized mask may be omitted in fabricating process to reduce process costs including a cost for forming or preparing the large-sized mask, and there may be no effect of failure occurring from the large-sized mask, such that process reliability of the display panel DP may be increased. In such an embodiment, features of the plurality of first emission patterns EP1 described above may be identically applicable to a plurality of second and third emission patterns EP2 and EP3.

The subsidiary electrodes SE1, SE2, and SE3 may include a first subsidiary electrode SE1, a second subsidiary electrode SE2, and a third subsidiary electrode SE3. The first subsidiary electrode SE1 may be disposed on the first emission element ED1, the second subsidiary electrode SE2 may be disposed on the second emission element ED2, and the third subsidiary electrode SE3 may be disposed on the third emission element ED3. The first, second, and third subsidiary electrodes SE1, SE2, and SE3 may extend along a first inner lateral surface (see S-L1 of FIG. 6) of the first partition layer L1, and may cover opposite ends of the first, second, and third emission patterns EP1, EP2, and EP3, respectively and opposite ends of the first, second, and third cathodes CE1, CE2, and CE3, respectively.

The first, second, and third subsidiary electrodes SE1, SE2, and SE3 may be in contact with the first inner lateral surface S-L1 of the first partition layer L1 and with the first, second, and third cathodes CE1, CE2, and CE3. In an embodiment, for example, the first subsidiary electrode SE1 may be electrically connected to the first partition layer L1 and the first cathode CE1, the second subsidiary electrode SE2 may be electrically connected to the first partition layer L1 and the second cathode CE2, and the third subsidiary electrode SE3 may be electrically connected to the first partition layer L1 and the third cathode CE3.

As the first to third subsidiary electrodes SE1 to SE3 are in contact with the first partition layer L1, the first to third subsidiary electrodes SE1 to SE3 may receive a common voltage via to the first partition layer L1, and as the first to third cathodes CE1 to CE3 are in contact with the first to third subsidiary electrodes SE1 to SE3, the first to third cathodes CE1 to CE3 may receive a common cathode voltage via the first to third subsidiary electrodes SE1 to SE3.

The dummy patterns DMP may include a plurality of first dummy patterns D1, a plurality of second dummy patterns D2, and a plurality of third dummy patterns D3.

The first dummy patterns D1 may include a first first dummy pattern D11, a second first dummy pattern D12, and a third first dummy pattern D13 that respectively surround the first emission region PXA-R, the second emission region PXA-G, and the third emission region PXA-B, when viewed in plan. The first first dummy pattern D11, the second first dummy pattern D12, and the third first dummy pattern D13 may include the same materials from those of the first emission pattern EP1, the second emission pattern EP2, and the third emission pattern EP3, respectively, and may be formed in the same processes as those used for forming the first emission pattern EP1, the second emission pattern EP2, and the third emission pattern EP3, respectively.

The second dummy patterns D2 may include a first second dummy pattern D21, a second second dummy pattern D22, and a third second dummy pattern D23 that respectively surround the first emission region PXA-R, the second emission region PXA-G, and the third emission region PXA-B, when viewed in plan. The first second dummy pattern D21, the second second dummy pattern D22, and the third second dummy pattern D23 may include the same materials as those of the first cathode CE1, the second cathode CE2, and the third cathode CE3, respectively, and may be formed in the same processes as those used for forming the first cathode CE1, the second cathode CE2, and the third cathode CE3, respectively.

The third dummy patterns D3 may include a first third dummy pattern D31, a second third dummy pattern D32, and a third third dummy pattern D33 that respectively surround the first emission region PXA-R, the second emission region PXA-G, and the third emission region PXA-B, when viewed in plan. The first third dummy pattern D31, the second third dummy pattern D32, and the third third dummy pattern D33 may include the same materials as those of the first subsidiary electrode SE1, the second subsidiary electrode SE2, and the third subsidiary electrode SE3, respectively, and may be formed in the same processes as those used for forming the first subsidiary electrode SE1, the second subsidiary electrode SE2, and the third subsidiary electrode SE3, respectively.

The dummy patterns DMP may be provided with a first dummy opening OP1-D, a second dummy opening OP2-D, and a third dummy opening OP3-D that are defined therethrough to respectively correspond to the first emission opening OP1-E, the second emission opening OP2-E, and the third emission opening OP3-E. The first dummy opening OP1-D, the second dummy opening OP2-D, and the third dummy opening OP3-D may respectively include a first region (see AA1 of FIG. 10F), a second region (see AA2 of FIG. 10F), and a third region (see AA3 of FIG. 10F) that are sequentially arranged in the third direction DR3. The first dummy opening OP1-D may be defined by inner lateral surfaces of the first first, first second, and first third dummy patterns D11, D21, and D31, the second dummy opening OP2-D may be defined by inner lateral surfaces of the second first, second second, and second third dummy patterns D12, D22, and D32, and the third dummy opening OP3-D may be defined by inner lateral surfaces of the third first, third second, and third third dummy patterns D13, D23, and D33.

The thin encapsulation layer TFE may include lower encapsulation inorganic patterns LIL1, LIL2, and LIL3, an encapsulation organic layer OL, and an upper encapsulation inorganic layer UIL. In an embodiment, the lower encapsulation inorganic patterns LIL1, LIL2, and LIL3 may include a first lower encapsulation inorganic pattern LIL1, a second lower encapsulation inorganic pattern LIL2, and a third lower encapsulation inorganic pattern LIL3. The first, second, and third lower encapsulation inorganic patterns LIL1, LIL2, and LIL3 may respectively overlap the first, second, and third emission openings OP1-E, OP2-E, and OP3-E.

The first lower encapsulation inorganic pattern LIL1 may cover the first subsidiary electrode SE1 and the first first, first second, and first third dummy patterns D11, D21, and D31, and a portion of the first lower encapsulation inorganic pattern LIL1 may be disposed inside the first partition opening OP1-P. The second lower encapsulation inorganic pattern LIL2 may cover the second subsidiary electrode SE2 and the second first, second second, and second third dummy patterns D12, D22, and D32, and a portion of the second lower encapsulation inorganic pattern LIL2 may be disposed inside the second partition opening OP2-P. The third lower encapsulation inorganic pattern LIL3 may cover the third subsidiary electrode SE3 and the third first, third second, and third third dummy patterns D13, D23, and D33, and a portion of the third lower encapsulation inorganic pattern LIL3 may be disposed inside the third partition opening OP3-P. The first, second, and third lower encapsulation inorganic patterns LIL1, LIL2, and LIL3 may be provided in the form of patterns that are spaced apart from each other.

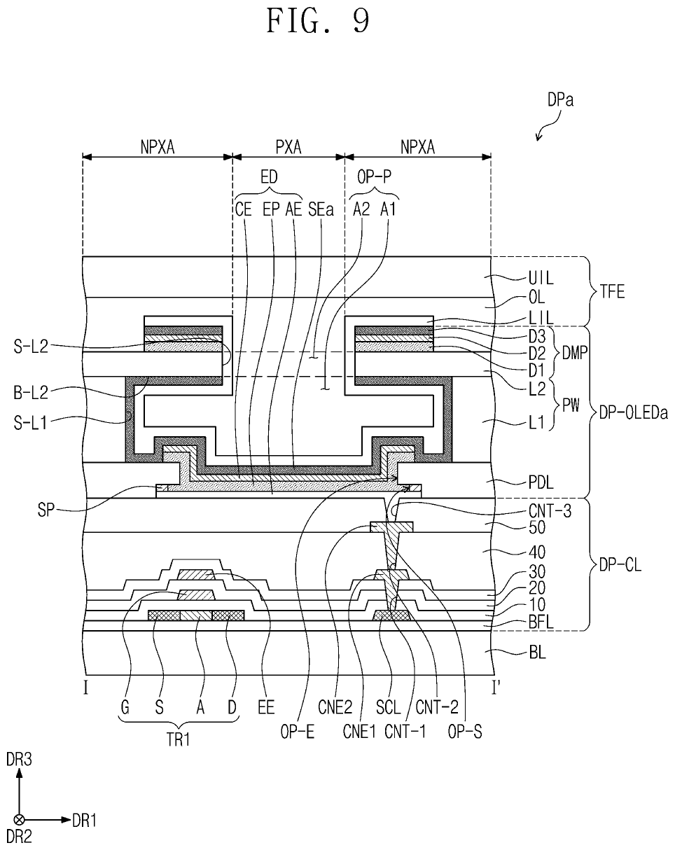

FIG. 9 illustrates a cross-sectional view taken along line I-I′ of FIG. 3, showing a display panel according to an embodiment of the invention. In FIG. 9, identical or similar reference numerals are allocated to identical or similar components to those shown in FIG. 6, and any repetitive detailed description thereof will be omitted.

Referring to FIG. 9, an embodiment of a display panel DPa may include a base layer BL, a circuit element layer DP-CL, a display element layer DP-OLEDa, and a thin encapsulation layer TFE. The display element layer DP-OLEDa may include an emission element ED, a sacrificial pattern SP, a pixel definition layer PDL, a partition wall PW, a subsidiary electrode SEa, and dummy patterns DMP. A shape of the subsidiary electrode SEa of FIG. 9 may be similar to that of the subsidiary electrode SE of FIG. 6.

The subsidiary electrode SEa may be disposed on the emission element ED. In an embodiment, for example, the subsidiary electrode SEa may be disposed on the cathode CE. A portion of the subsidiary electrode SEa may be disposed on the partition opening OP-P. In an embodiment, as shown in FIG. 9, the subsidiary electrode SEa may extend along the first inner lateral surface S-L1 of the first partition layer L1 and a bottom surface B-L2 of the second partition layer L2, and may cover opposite ends of the emission pattern EP and opposite ends of the cathode CE. FIG. 9 an embodiment where the subsidiary electrode SEa extends to align with the second inner lateral surface S-L2 of the second partition layer L2, but the invention is not limited thereto. In an embodiment, for example, the subsidiary electrode SEa may extend only to an intermediate portion of (or extend to cover only a portion of) the bottom surface B-L2 of the second partition layer L2.

The subsidiary electrode SEa may have conductivity. In an embodiment, for example, the subsidiary electrode SEa may include titanium nitride (TiN). In another embodiment of the invention, the subsidiary electrode SEa may include transparent conductive oxide (TCO). In an embodiment, for example, the subsidiary electrode SEa may include indium tin oxide (ITO) or indium zinc oxide (IZO). The invention, however, is not limited thereto, and the subsidiary electrode SEa may include or be formed of any material as long as the material has conductivity, such as a conductive polymer material.

The subsidiary electrode SEa may be in contact with the cathode CE and the first inner lateral surface S-L1 of the first partition layer L1. In an embodiment, for example, the subsidiary electrode SEa may be electrically connected to the partition wall PW and the cathode CE. The partition wall PW may receive the second driving voltage (see ELVSS of FIG. 3B), and the subsidiary electrode SEa may be electrically coupled to the partition wall PW to receive the second driving voltage ELVSS. Therefore, the cathode CE electrically connected to the subsidiary electrode SEa may receive the second driving voltage ELVSS.

FIGS. 10A to 10J illustrate cross-sectional views showing some steps of a method of fabricating a display panel according to an embodiment of the invention. In FIGS. 10A to 10J, identical or similar reference numerals are allocated to identical or similar components as those shown in FIGS. 1 to 9, and any repetitive detailed description will be omitted.

A method of fabricating a display panel according to an embodiment of the invention may include providing a preliminary display panel that includes a base layer, a pixel definition layer disposed on the base layer, a first preliminary partition layer disposed on the pixel definition layer, and a second preliminary partition layer disposed on the first preliminary partition layer, etching the first preliminary partition layer and the second preliminary partition layer to form a first partition layer and a second partition layer in which partition openings are defined, forming, in the partition opening, an emission pattern and a cathode which are spaced apart from the second partition layer when viewed in plan, and forming, on the cathode, a subsidiary electrode in contact with the second partition layer and including titanium nitride (TiN).

With reference to FIGS. 10A to 10J, an embodiment of a method of forming two emission elements ED1 and ED2 and lower encapsulation inorganic patterns LIL1, LIL2, and LIL3, an encapsulation organic layer OL, and an upper encapsulation inorganic layer UIL that cover the two emission elements ED1 and ED2 will be described. A display panel DP formed by processes illustrated in FIGS. 10A to 10J may correspond to the display panel DP of FIG. 7.

Referring to FIG. 10A, a method of fabricating a display panel according to an embodiment may include providing a preliminary display panel DP-I. In such an embodiment, the preliminary display panel DP-I may include a base layer BL, a circuit element layer DP-CL, first and second anodes AE1 and AE2, first and second preliminary sacrificial patterns SP1-I and SP2-I, a pixel definition layer PDL, a first preliminary partition layer L1-I, and a second preliminary partition layer L2-I.

The circuit element layer DP-CL may be formed by a typical circuit fabrication process in which coating and deposition processes are employed to form a dielectric layer, a semiconductor layer, and a conductive layer, and then photolithography and etching processes are performed to selectively pattern the dielectric layer, the semiconductor layer, and the conductive layer to form a semiconductor pattern, a conductive pattern, and a signal line.

The first anode AE1 and the first preliminary sacrificial pattern SP1-I may be formed in a same patterning process, and the second anode AE2 and the second preliminary sacrificial pattern SP2-I may be formed in a same patterning process. The pixel definition layer PDL may be disposed on the base layer BL. The pixel definition layer PDL may cover all of the first and second anodes AE1 and AE2 and the first and second preliminary sacrificial patterns SP1-I and SP2-I.

The first preliminary partition layer L1-I may be disposed on the pixel definition layer PDL. The first preliminary partition layer L1-I may be formed by a deposition process in which a conductive material is deposited. The second preliminary partition layer L2-I may be disposed on the first preliminary partition layer L1-I. The second preliminary partition layer L2-I may be formed by a deposition process in which a conductive material is deposited. In an embodiment, the first preliminary partition layer L1-I may include aluminum (Al) or molybdenum (Mo), and the second preliminary partition layer L2-I may include titanium (Ti), but the materials of the first and second preliminary partition layers L1-I and L2-I are not limited thereto. The first preliminary partition layer L1-I and the second preliminary partition layer L2-I may form a preliminary partition wall PW-I.

Subsequently, the method of fabrication a display panel according to an embodiment may include forming a first photoresist layer PRI on the preliminary partition wall PW-I. The first photoresist layer PRI may be formed by forming a preliminary photoresist layer on the preliminary partition wall PW-I, and then using a photomask to pattern the preliminary photoresist layer. In the patterning process, a first photo-opening OP-PR1 and a second photo-opening OP-PR2 may be formed in the first photoresist layer PR1. The first photo-opening OP-PRI may overlap the first anode AE1, and the second photo-opening OP-PR2 may overlap the second anode AE2.

Referring to FIGS. 10B and 10C, to form a partition wall PW from the preliminary partition wall (see PW-I of FIG. 10A), the method of fabricating a display panel according to an embodiment may include etching the first preliminary partition layer L1-I and the second preliminary partition layer L2-I to form a first partition layer L1 and a second partition layer L2 with partition openings OP1-P and OP2-P defined therein.

In an embodiment, as shown in FIG. 10B, a first etching process may be performed on the first preliminary partition layer L1-I and the second preliminary partition layer L2-I such that the first photoresist layer PRI is used as a mask to dry-etch the first preliminary partition layer L1-I and the second preliminary partition layer L2-I to thereby form preliminary partition openings OP1-PI and OP2-PI in the preliminary partition wall (see PW-I of FIG. 10A). The preliminary partition openings OP1-PI and OP2-PI may include a first preliminary partition opening OP1-PI and a second preliminary partition opening OP2-PI. The first preliminary partition opening OP1-PI may be formed overlapping the first anode AE1, and the second preliminary partition opening OP2-PI may be formed overlapping the second anode AE2.

In an embodiment, the first dry etching process may be performed in an environment where there is substantially the same etch selectivity between the first preliminary partition layer L1-I and the second preliminary partition layer L2-I. Therefore, the first preliminary partition layer L1-I and the second preliminary partition layer L2-I may have substantially aligned inner lateral surfaces that define the first and second preliminary openings OP1-PI and OP2-PI after performing the first dry etching process.

As shown in FIG. 10C, a second etching process may be performed on the first preliminary partition layer (see L1-I of FIG. 10B) such that the first photoresist layer PRI is used as a mask to wet-etch the first preliminary partition layer L1-I to thereby form partition openings OP1-P and OP2-P from the preliminary partition openings (see OP1-PI and OP2-PI of FIG. 10B). The partition openings OP1-P and OP2-P may include a first partition opening OP1-P and a second partition opening OP2-P. The first partition opening OP1-P may be formed to overlap the first anode AE1, and the second partition opening OP2-P may be formed to overlap the second anode AE2.

Each of the partition openings OP1-P and OP2-P may include a first region A1 and a second region A2 that are sequentially disposed in a thickness direction (or the third direction DR3) thereof. The first partition layer L1 may include a first inner lateral surface S-L1 that defines the first region A1 of each of the partition openings OP1-P and OP2-P, and the second partition layer L2 may include a second inner lateral surface S-L2 that defines the second region A2 of each of the partition openings OP1-P and OP2-P.

Referring to FIGS. 6, 7, and 10C, the process of forming the first partition layer L1 and the second partition layer L2 may include forming on the second partition layer L2 a tip TP that protrudes from the first partition layer L1 toward a corresponding one of the partition openings OP1-P and OP2-P. In an embodiment, the second wet etching process may be performed in an environment where there is a high etch selectivity between the first preliminary partition layer L1-I and the second preliminary partition layer L2-I. Therefore, when viewed in cross section, an undercut shape may be given to an inner lateral surface of the partition wall PW that defines the partition openings OP1-P and OP2-P. In an embodiment, for example, the first partition layer L1 may have a high etch rate with respect to an etching solution compared to the second partition layer L2. Therefore, the first inner lateral surface S-L1 of the first partition layer L1 may be formed more recessed than the second inner lateral surface S-L2 of the second partition layer L2. The second partition layer L2 may have a portion that protrudes than the first partition layer L1, and the protruding portion of the second partition layer L2 may correspond to the tip TP of the partition wall PW.

A length D-TP in the first direction DR1 of the tip TP of the second partition layer L2 may be a length between the first inner lateral surface S-L1 of the first partition layer L1 that overlaps the pixel definition layer PDL and the second inner lateral surface S-L2 of the second partition layer L2. In an embodiment, the length D-TP in the first direction DR1 of the tip TP may be equal to or greater than about 1.5 times a thickness T-L1 of the first partition layer L1.

Referring to FIG. 10D, the method of fabricating a display panel according to an embodiment may include etching the pixel definition layer PDL and etching the preliminary sacrificial patterns (see SP1-I and SP2-I of FIG. 10C). A dry etching process may be performed in which the first photoresist layer PRI and the partition wall PW (e.g., the second partition layer L2) are used as a mask to etch the pixel definition layer PDL. The pixel definition layer PDL may be etched to define emission openings OP1-E and OP2-E that correspond to the partition openings OP1-P and OP2-P. The emission openings OP1-E and OP2-E may include a first emission opening OP1-E and a second emission opening OP2-E.

A wet etching process may be performed in which the first photoresist layer PR1 and the partition wall PW (e.g., the second partition layer L2) are used as a mask to etch the preliminary sacrificial patterns SP1-I and SP2-I. The preliminary sacrificial patterns SP1-I and SP2-I may be etched to form sacrificial patterns SP1 and SP2 including sacrificial openings OP1-S and OP2-S that overlap the emission openings OP1-E and OP2-E.

The sacrificial patterns SP1 an SP2 may include a first sacrificial pattern SP1 and a second sacrificial pattern SP2. The first sacrificial pattern SP1 may be formed to define a first sacrificial opening OP1-S that overlaps the first emission opening OP1-E, and the second sacrificial pattern SP2 may be formed to define a second sacrificial opening OP2-S that overlaps the second emission opening OP2-E. The first sacrificial opening OP1-S and the first emission opening OP1-E may cause at least a portion of the first anode AE1 to be exposed from the first sacrificial pattern SP1 and the pixel definition layer PDL, and the second sacrificial opening OP2-S and the second emission opening OP2-E may cause at least a portion of the second anode AE2 to be exposed from the second sacrificial pattern SP2 and the pixel definition layer PDL.

An etching process for forming the sacrificial patterns SP1 and SP2 may be performed in an environment where there is a high etch selectivity between the sacrificial patterns SP1 and SP2 and the anodes AE1 and AE2, and thus the anodes AE1 and AE2 may be effectively prevented from being etched together with the preliminary sacrificial patterns SP1-I and SP2-I. In an embodiment, for example, the sacrificial patterns SP1 and SP2 whose etch rate is higher than that of the anodes AE1 and AE2 may be disposed between the pixel definition layer PDL and the anodes AE1 and AE2, and therefore the anodes AE1 and AE2 may be effectively prevented from being etched and damaged during the etching process for forming the sacrificial patterns SP1 and SP2.

Referring to FIGS. 10E to 10H, the method of fabricating a display panel according to an embodiment may include removing the first photoresist layer (see PR1 of FIG. 10D), forming a first emission pattern EP1 (or an emission pattern) and a first cathode CE1 (or a cathode) in the partition openings OP1-P and OP2-P, and forming a first subsidiary electrode SE1 (or a subsidiary electrode).

Referring to FIG. 10E, the process of forming the first emission pattern (see EP1 of FIG. 10H) may include depositing an emission layer EP-I. The step of depositing the emission layer EP-I may include a thermal evaporation process. In addition, the process of forming the first cathode (see CE1 of FIG. 10H) may include depositing a cathode layer CE-I. The process of depositing the cathode layer CE-I may include a thermal evaporation process.

In the process of forming the first emission pattern EP1, the emission layer EP-I may be formed on the anodes AE1 and AE2. The emission layer EP-I may be divided by the tip of the partition wall PW to be disposed in the emission openings OP1-E and OP2-E and the partition openings OP1-P and OP2-P. When viewed in plan, in the partition openings OP1-P and OP2-P, the emission layer EP-I may be formed to be spaced apart from the second partition layer L2. In the process of forming the first emission pattern EP1, a first dummy layer D1-I spaced apart from the emission layer EP-I may also be formed on the partition wall PW.

In the process of forming the first cathode CE1, the cathode layer CE-I may be formed on the emission layer EP-I. The cathode layer CE-I may be divided by the tip of the partition wall PW to be disposed in the partition openings OP1-P and OP2-P. When viewed in plan, in the partition openings OP1-P and OP2-P, the cathode layer CE-I may be formed to be spaced apart from the second partition layer L2. In the process of forming the first cathode CE1, a second dummy layer D2-I spaced apart from the cathode layer CE-I may also be formed on the partition wall PW.

Referring to FIG. 10F, the process of forming the first subsidiary electrode SE1 may include depositing a preliminary subsidiary electrode SE-I.

In the process of forming the first subsidiary electrode SE1, the preliminary subsidiary electrode SE1 may be disposed on the cathode layer CE-I. The preliminary subsidiary electrode SE1 may be divided by the tip of the partition wall PW to be disposed in the partition openings OP1-P and OP2-P. The preliminary subsidiary electrode SE1 may be formed to cover the emission layer EP-I and the cathode layer CE-I. In an embodiment, for example, the preliminary subsidiary electrode SE1 may be deposited to cover opposite ends of the emission layer EP-I and opposite ends of the cathode layer CE-I. In this configuration, the preliminary subsidiary electrode SE1 may be deposited to cover opposite ends of the first emission pattern (see EP1 of FIG. 10H) which will be formed subsequently and opposite ends of the first cathode (see CE1 of FIG. 10H) which will be formed subsequently. In the process of forming the first subsidiary electrode SE1, a third dummy layer D3-I spaced apart from the preliminary subsidiary electrode SE1 may also be formed on the partition wall PW.

In an embodiment, the process of depositing the preliminary subsidiary electrode SE1 may include a sputtering process. The preliminary subsidiary electrode SE1 may be provided at an incident angle greater than those of the emission layer EP-I and the cathode layer CE-I, and may thus be formed in contact with the first partition layer L1. The preliminary subsidiary electrode SE1 may be formed to extend along the first inner lateral surface S-L1 of the first partition layer L1. FIG. 10F shows an embodiment where the preliminary subsidiary electrode SE1 is in contact with the first inner lateral surface S-L1 of the first partition layer L1, but the invention is not limited thereto. In an embodiment, for example, the preliminary subsidiary electrode SE1 may extend along the first inner lateral surface S-L1 of the first partition layer L1 and a bottom surface B-L2 of the second partition layer L2, as shown in FIG. 9.

The process of forming the first subsidiary electrode SE1 may include depositing the preliminary subsidiary electrode SE1 including a conductive material. In an embodiment, for example, the preliminary subsidiary electrode SE1 may include titanium nitride (TiN). In a process for sputtering the preliminary subsidiary electrode SE1 including titanium nitride (TiN), the titanium nitride (TiN) may be directly sputtered or a nitrogen (N₂) gas is introduced and sputtered when a titanium (Ti) layer is formed.

In an embodiment, the preliminary subsidiary electrode SE1 may include transparent conductive oxide (TCO), indium tin oxide (ITO), or indium zinc oxide (IZO). The invention, however, is not limited thereto, and the preliminary subsidiary electrode SE1 may be formed of any material as long as the material has conductivity, such as a conductive polymer material.

The first, second, and third dummy layers D1-I, D2-I, and D3-I may form a dummy layer DMP-I, and dummy openings OP1-D and OP2-D may be formed in the dummy layer DMP-I. The dummy openings OP1-D and OP2-D may include a first dummy opening OP1-D and a second dummy opening OP2-D. The first dummy opening OP1-D may overlap the first partition opening OP1-P, and the second dummy opening OP2-D may overlap the second partition opening OP2-P.

Each of the dummy openings OP1-D and OP2-D may include a first region AA1, a second region AA2, and a third region AA3 that are sequentially disposed in a thickness direction thereof (or the third direction DR3). The first region AA1 of each of the dummy openings OP1-D and OP2-D may be defined by an inner lateral surface of the first dummy layer D1-I, the second region AA2 of each of the dummy openings OP1-D and OP2-D may be defined by an inner lateral surface of the second dummy layer D2-I, and the third region AA3 of each of the dummy openings OP1-D and OP2-D may be defined by an inner lateral surface of the third dummy layer D3-I.

Referring to FIG. 10G, the method of fabricating a display panel according to an embodiment may include forming a lower encapsulation inorganic layer LIL1. The lower encapsulation inorganic layer LIL1 may be formed by a deposition process. In an embodiment, the lower encapsulation inorganic layer LIL1 may be formed by a chemical vapor deposition (CVD) process. The lower encapsulation inorganic layer LIL1 may be formed on the partition wall PW and the preliminary subsidiary electrode SE1 and a portion of the lower encapsulation inorganic layer LIL1 may be formed inside the partition openings OP1-P and OP2-P. The lower encapsulation inorganic layer LIL1 may be in direct contact with the preliminary subsidiary electrode SE-I.

In such an embodiment, the method of fabricating a display panel may include forming a second photoresist layer PR2. The second photoresist layer PR2 may be formed by forming a preliminary photoresist layer, and then using a photomask to pattern the preliminary photoresist layer. Through the patterning process, the second photoresist layer PR2 may be formed to have a pattern that corresponds to the first emission opening OP1-E.

Referring to FIG. 10H, the method of fabricating a display panel according to an embodiment may include patterning the lower encapsulation inorganic layer (see LIL1 of FIG. 10G) to form a first lower encapsulation inorganic pattern LIL1, patterning the preliminary subsidiary electrode (see SE1 of FIG. 10G) to form the first subsidiary electrode SE1, patterning the emission layer (see EP-I of FIG. 10G) and the cathode layer (see CE-I of FIG. 10G) to form the first emission pattern EP1 and the first cathode CE1, and patterning the dummy layer (see DMP-I of FIG. 10G) to form first first, first second, and first third dummy patterns D11, D21, and D31.

In the process of patterning the lower encapsulation inorganic layer LIL1, the lower encapsulation inorganic layer LIL1 may be dry-etched to remove a portion thereof that does not overlap the second photoresist layer PR2. In an embodiment, for example, a portion of the lower encapsulation inorganic layer LIL1 that does not overlap the first anode AE1 may be removed. The patterned lower encapsulation inorganic layer LIL1 may be formed into the first lower encapsulation inorganic pattern LIL1 that overlaps the first emission opening OP1-E.

In the process of patterning the preliminary subsidiary electrode SE1 the preliminary subsidiary electrode SE1 may be dry-etched to remove a portion thereof that does not overlap the second photoresist layer PR2. In an embodiment, for example, a portion of the preliminary subsidiary electrode SE1 that does not overlap the first anode AE1 may be removed. The patterned preliminary subsidiary electrode SE1 may be formed into the first subsidiary electrode SE1 that overlaps the first emission opening OP1-E.

In the process of patterning the emission layer EP-I and the cathode layer CE-I, the emission layer EP-I and the cathode layer CE-I may be removed by wet etching and stripping. Portions of the emission layer EP-I and the cathode layer CE-I that do not overlap the second photoresist layer PR2 may be removed. In an embodiment, for example, portions of the emission layer EP-I and the cathode layer CE-I that do not overlap the first anode AE1 may be removed. The patterned emission layer EP-I and the patterned cathode layer CE-I may be formed into the first emission pattern EP1 and the first cathode CE1 that overlap the first emission opening OP1-E.

In the process of patterning the dummy layer DMP-I, the first, second, and third dummy layers (see D1-I, D2-I, and D3-I of FIG. 10G) may be dry-etched such that portions thereof that do not overlap the second photoresist layer PR2 may be removed. In an embodiment, for example, the first, second, and third dummy layers D1-I, D2-I, and D3-I may be patterned to remove portions thereof that do not overlap the first anode AE1. The patterned first, second, and third dummy layers D1-I, D2-I, and D3-I may be formed into the first first, first second, and first third dummy patterns D11, D21, and D31 that overlap the first emission opening OP1-E. When viewed in plan, each of the first, second, and third dummy layers D1-I, D2-I, and D3-I may have a closed line shape that surrounds a corresponding emission region (see PXA of FIG. 5).

Through the patterning process, the emission layer EP-I, the cathode layer CE-I, the preliminary subsidiary electrode SE1 and the lower encapsulation inorganic layer LIL1 may be removed from the second emission opening OP2-E and the second partition opening OP2-P. In addition, portions of the first, second, and third dummy layers D1-I, D2-I, and D3-I which are formed on the partition wall PW and do not overlap the first emission opening OP1-E may also be removed. After the patterning process, a first emission element ED1 may be constituted by the first anode AE1, the first emission pattern EP1, and the first cathode CE1 that are formed in the first emission opening OP1-E and the first partition opening OP1-P.

In an embodiment, after the patterning process, a portion of the preliminary subsidiary electrode SE1 may not be removed from the second partition opening OP2-P. In an embodiment, for example, a portion of the preliminary subsidiary electrode SE1 in contact with the first inner lateral surface S-L1 of the first partition layer L1 may not be removed in the second partition opening OP2-P. The preliminary subsidiary electrode SE1 may have selectivity less than that of the first partition layer L1, and it may thus be possible to reduce or eliminate erosion of the first partition layer L1 on which the preliminary subsidiary electrode SE1 remains.

In addition, according to an embodiment of the invention, as a second emission pattern (see EP2 of FIG. 101) and a second cathode (see CE2 of FIG. 101), which will be described alter, are formed to be spaced apart from the first partition layer L1 when viewed in plan, the preliminary subsidiary electrode SE1 remaining in contact with the first partition layer L1 in the second partition opening OP2-P may be combined with a second subsidiary electrode (see SE2 of FIG. 101) which will be formed after the second emission pattern EP2 and the second cathode CE2 are deposited, and accordingly there may be an increase in electrical connection between the partition wall PW and the second subsidiary electrode SE2.

Referring to FIG. 101, the method of fabricating a display panel according to an embodiment may include removing the second photoresist layer (see PR2 of FIG. 10H), and then forming a second emission element ED2. The formation process of the second emission element ED2 may be substantially the same as the formation process of the first emission element ED1 described above with reference to FIGS. 10E to 10H.

Referring to FIG. 10J, the method of fabricating a display panel according to an embodiment may include forming an encapsulation organic layer OL and an upper encapsulation inorganic layer UIL to accomplish a display panel DP. The encapsulation organic layer OL may be formed by using an inkjet manner to coat an organic material, but the invention is not limited thereto. The encapsulation organic layer OL may provide a planarized top surface. Thereafter, an inorganic material may be deposited to form the upper encapsulation inorganic layer UIL. Therefore, the display panel DP may be formed which includes a base layer BL, a circuit element layer DP-CL, a display element layer DP-OLED, and a thin encapsulation layer TFE.

FIGS. 10A to 10J show an embodiment of a method of fabricating the display panel DP including the first and second emission elements ED1 and ED2. In an embodiment, a process of forming a third emission element (see ED3 of FIG. 8), a process of forming a third subsidiary electrode (see SE3 of FIG. 8), and a process of forming a third lower encapsulation inorganic pattern LIL3 may further be included between the process of forming the second lower encapsulation inorganic pattern LIL2 that overlaps the second emission element ED2 and the process of accomplishing the display panel DP. Therefore, the display panel DP may be formed to include first, second, and third emission elements ED1, ED2, and ED3, first, second, and third subsidiary electrodes SE1, SE2, and SE3, first, second, and third dummy patterns D1, D2, and D3, and first, second, and third lower encapsulation inorganic patterns LIL1, LIL2, and LIL3 that correspond to a plurality of emission regions PXA-R, PXA-G, and PXA-B depicted in FIG. 8.

According to embodiments of the invention, as above, as a second partition layer includes a tip formed thereon, and as a length in a first direction of the tip is equal to greater than about 1.5 times a thickness of a first partition layer, an emission pattern and a cathode may be formed not to be in contact with a partition wall. Accordingly, the occurrence of leakage current may be effectively prevented even when a portion (e.g., a p-doped hole injection layer) of the emission pattern has conductivity.

In such embodiments, the cathode may be electrically connected to the partition wall through a subsidiary electrode, without being direct contact with the partition wall. A bonding force between the subsidiary electrode and the cathode and between the subsidiary electrode and the partition wall may be greater than that between the cathode and the partition wall. Accordingly, delamination of the cathode in contact with the partition wall may be effectively prevented such that foreign substances may be effectively prevented from being introduced into a display element layer. In such embodiments, as the subsidiary electrode including titanium nitride has high resistance to chemicals, the display element layer may have high durability and a display panel may have an increased life span.

In a patterning process of the subsidiary electrode in an embodiment of a method of fabricating the display panel, there may be no partial removal of a preliminary subsidiary electrode in contact with a first inner lateral surface of the first partition layer in a second partition opening. The preliminary subsidiary electrode may have selectivity less than that of the first partition layer, and it may thus be possible to reduce or eliminate erosion of the first partition layer on which the preliminary subsidiary electrode remains. In such an embodiment, as a second emission pattern and a second cathode are formed to be spaced apart from the first partition layer when viewed in plan, the preliminary subsidiary electrode remaining in contact with the first partition layer in the second partition opening may be combined with a second subsidiary electrode, which will be formed after the second emission pattern and the second cathode are deposited, such that electrical connection between the partition wall and the second subsidiary electrode may be increased.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel, comprising:
a base layer;
a pixel definition layer on the base layer, wherein an emission opening is defined in the pixel definition layer;
a partition wall including a first partition layer on the pixel definition layer and a second partition layer on the first partition layer, wherein a partition opening is defined in the partition wall to overlap the emission opening;
an emission element including an anode, an intermediate layer on the anode, and a cathode on the intermediate layer; and
a subsidiary electrode on the emission element,
wherein the intermediate layer and the cathode are spaced apart from a lateral surface of the partition wall when viewed in plan, and
wherein the subsidiary electrode is in contact with the partition wall.

2. The display panel of claim 1, wherein the subsidiary electrode covers both ends of the intermediate layer and both ends of the cathode.

3. The display panel of claim 1, wherein the subsidiary electrode is in contact with a first inner lateral surface of the first partition layer and is electrically connected to the partition wall.

4. The display panel of claim 1, wherein the subsidiary electrode includes titanium nitride (TiN).

5. The display panel of claim 1, wherein the subsidiary electrode extends along a first inner lateral surface of the first partition layer.

6. The display panel of claim 1, wherein the subsidiary electrode extends along a first inner lateral surface of the first partition layer and a bottom surface of the second partition layer.

7. The display panel of claim 1, wherein the second partition layer includes a tip which protrudes from the first partition layer toward a center of the partition opening,
wherein a length in a first direction of the tip is equal to or greater than about 1.5 times a thickness of the first partition layer.

8. The display panel of claim 1, wherein a thickness of the second partition layer is in a range of about 2,000 Å to about 3,000 Å.

9. A display panel, comprising:
a base layer;
a pixel definition layer on the base layer, wherein an emission opening is defined in the pixel definition layer;
a partition wall including a first partition layer on the pixel definition layer and a second partition layer on the first partition layer, wherein a partition opening is defined in the partition wall to correspond to the emission opening;
an emission element including an anode, an intermediate layer on the anode, and a cathode on the intermediate layer; and
a subsidiary electrode on the emission element,
wherein the second partition layer includes a tip which protrudes from the first partition layer toward a center of the partition opening,
wherein a length in a first direction of the tip is equal to or greater than about 1.5 times a thickness of the first partition layer.

10. The display panel of claim 9, wherein
the intermediate layer and the cathode are spaced apart from a lateral surface of the partition wall when viewed in plan, and
the subsidiary electrode is in contact with the partition wall.

11. The display panel of claim 9, wherein the subsidiary electrode covers both ends of the intermediate layer and both ends of the cathode.

12. The display panel of claim 9, wherein the subsidiary electrode is in contact with a first inner lateral surface of the first partition layer and is electrically connected to the partition wall.

13. The display panel of claim 9, wherein the subsidiary electrode includes titanium nitride (TiN).

14. The display panel of claim 9, wherein the subsidiary electrode extends along a first inner lateral surface of the first partition layer.

15. The display panel of claim 9, wherein the subsidiary electrode extends along a first inner lateral surface of the first partition layer and a bottom surface of the second partition layer.

16. The display panel of claim 9, wherein a thickness of the second partition layer is in a range of about 2,000 Å to about 3,000 Å.

17. A method of fabricating a display panel, the method comprising:
providing a preliminary display panel which includes a base layer, a pixel definition layer on the base layer, a first preliminary partition layer on the pixel definition layer, and a second preliminary partition layer on the first preliminary partition layer;
etching the first preliminary partition layer and the second preliminary partition layer to form a first partition layer and a second partition layer with partition openings defined therein;
forming, in the partition openings, an emission pattern and a cathode, which are spaced apart from the second partition layer when viewed in plan; and
forming, on the cathode, a subsidiary electrode in contact with the first partition layer, wherein the subsidiary electrode includes titanium nitride (TiN).

18. The method of claim 17, wherein
the forming the emission pattern and the cathode includes performing a thermal evaporation process, and
the forming the subsidiary electrode includes performing a sputtering process.

19. The method of claim 17, wherein the forming the subsidiary electrode includes depositing a preliminary subsidiary electrode to cover both ends of the emission pattern and both ends of the cathode.

20. The method of claim 17, wherein the forming the first partition layer and the second partition layer includes forming, in the second partition layer, a tip which protrudes from the first partition layer toward a center of the partition openings,
wherein a length in a first direction of the tip is equal to or greater than about 1.5 times a thickness of the first partition layer.
